(19) United States
(12) Patent Application Publication
(10) Pub. No.: US 2026/0051883 A1
(43) Pub. Date: Feb. 19, 2026

(54) GATE DRIVER CIRCUIT and CHIP

(71) Applicant: Zhuhai Nanxin Semiconductor Technology Co., Ltd., Zhuhai City (CN)

(72) Inventor: Ziwei Li, Zhuhai City (CN)

(21) Appl. No.: 19/296,617

(22) Filed: Aug. 11, 2025

(30) Foreign Application Priority Data
Aug. 13, 2024 (CN) 202411111322.3

(51) Int. Cl. H03K 17/0416; H03K 19/21

(52) U.S. Cl. CPC H03K 17/04163; H03K 19/215; H03K 2217/0036

(57) ABSTRACT

A first current output circuit transmits a first current to a channel selection circuit. The channel selection circuit selects a transmission channel for the first current based on a control signal, and transmits the first current to an output stage circuit over the transmission channel. Further, the output stage circuit outputs a second current based on the first current, such that the gate driver circuit drives a switch transistor to be turned on or turned off. Since one control circuit is provided in the channel selection circuit, hardware in the gate driver circuit is reduced to lower the cost of the gate driver circuit. In addition, since one control circuit is provided, the number of voltage sources arranged inside the control circuit is also one to reduce static power consumption of the control circuit, such that power consumption of the gate driver circuit is reduced.

### CROSS-REFERENCE TO RELATED APPLICATION

This application is based upon and claims the priority of Chinese Patent Application No. 202411111322.3, filed on Aug. 13, 2024, the entire contents of which are hereby incorporated by reference.

### TECHNICAL FIELD

The present application relates to the technical field of integrated circuits, and in particular, relates to a gate driver circuit and a chip.

### BACKGROUND

Typically, gate driver circuits are widely used in electronic devices such as motor control systems, switch power supplies, and household appliances. Currently, a gate driver circuit usually transmits a current signal serving as a reference current to an output pull-up circuit and an output pull-down circuit, such that the output pull-up circuit generates a pull-up current and the output pull-down circuit generates a pull-down current. In this way, the gate driver circuit may charge a gate electrode of a driven transistor using the pull-up current or discharge the gate electrode of the driven transistor using the pull-down current.

However, the gate drive circuit in related arts suffers from issues such as high power consumption and high cost. As a result, electronic devices equipped with such gate drive circuits face challenges of increased power consumption and higher cost.

### SUMMARY

Embodiments of the present application provide a gate driver circuit, a chip and an electronic device, which are capable of reducing the power consumption and cost.

In a first aspect, the embodiments of the present application provide a gate driver circuit. The gate driver circuit includes: a first current output circuit, a channel selection circuit, and an output stage circuit.

An output terminal of the first current output circuit is electrically connected to a first terminal of the channel selection circuit, a second terminal of the channel selection circuit is configured to receive a control signal, the control signal being used for controlling the gate driver circuit to drive a switch transistor to be turned on or turned off, a third terminal of the channel selection circuit is electrically connected to a first input terminal of the output stage circuit, a fourth terminal of the channel selection circuit is electrically connected to a second input terminal of the output stage circuit, and an output terminal of the output stage circuit is electrically connected to a gate electrode of the switch transistor; wherein one control circuit is arranged in the channel selection circuit.

The first current output circuit is configured to transmit a first current to the channel selection circuit, the first current serving as a reference current.

The channel selection circuit is configured to select a transmission channel for the first current based on the control signal, and transmit the first current to the output stage circuit over the transmission channel.

The output stage circuit is configured to output a second current based on the first current to drive the switch transistor to be turned on or turned off, the second current being used for pulling up or pulling down a gate voltage of the switch transistor.

In the gate driver circuit according to the first aspect, the first current output circuit may transmit the first current serving as the reference current to the channel selection circuit, such that the channel selection circuit is capable of obtaining the first current. The channel selection circuit is configured to select a transmission channel for the first current based on the control signal for controlling the gate driver circuit to drive the switch transistor to be turned on or turned off, and transmit the first current to the output stage circuit over the transmission channel, such that the output stage circuit is capable of obtaining the first current. Further, the output stage circuit may output the second current based on the first current, and pull up or pull down the gate voltage of the switch transistor using the second current, such that the gate driver circuit may drive the switch transistor to be turned on or turned off. Since one control circuit is provided in the channel selection circuit, hardware in the gate driver circuit is reduced to lower the cost of the gate driver circuit. In addition, since one control circuit is provided, the number of voltage sources arranged inside the control circuit is also one to reduce static power consumption of the control circuit, such that power consumption of the gate driver circuit is reduced. In this way, the cost and power consumption of the gate driver circuit are reduced, such that the cost and power consumption of the electronic device equipped with the gate driver circuit are both reduced.

In some embodiments, the output stage circuit includes an output pull-up circuit, an output pull-down circuit, and a clamp circuit.

A first terminal of the output pull-up circuit is electrically connected to the third terminal of the channel selection circuit, a second terminal of the output pull-up circuit is electrically connected to the gate electrode of the switch transistor, a first terminal of the output pull-down circuit is electrically connected to the fourth terminal of the channel selection circuit, a second terminal of the output pull-down circuit is electrically connected to a source electrode of the switch transistor, a third terminal of the output pull-down circuit is electrically connected between a third terminal of the output pull-up circuit and the gate electrode of the switch transistor, a first terminal of the clamp circuit is electrically connected between the first terminal of the output pull-up circuit and the third terminal of the channel selection circuit, and a second terminal of the clamp circuit is electrically connected between the second terminal of the output pull-down circuit and the source electrode of the switch transistor.

The output pull-up circuit is configured to, in a case where the transmission channel is a pull-up channel, convert the first current to obtain a pull-up current, and transmit the pull-up current to the switch transistor to drive the switch transistor to be turned on, wherein the pull-up current is the second current.

The output pull-down circuit is configured to, in a case where the transmission channel is a pull-down channel, convert the first current to obtain a pull-down current, and transmit the pull-down current to the switch transistor to drive the switch transistor to be turned off, wherein the pull-down current is the second current.

The clamp circuit is configured to, in a case where the transmission channel is the pull-up channel and the gate voltage of the switch transistor is greater than or equal to a predetermined voltage, pull down the pull-up current to a predetermined current to clamp a gate-source voltage of the switch transistor.

In some embodiments, the output pull-up circuit includes a first current mirror.

A first terminal of the first current mirror is configured to be connected to the supply voltage, a second terminal of the first current mirror is electrically connected to the third terminal of the channel selection circuit, and a third terminal of the first current mirror is electrically connected to the gate electrode of the switch transistor.

The first current mirror is configured to convert the first current to obtain the pull-up current.

Alternatively, the output pull-up circuit includes a first current mirror, a first transistor, and a first voltage-limiting assembly.

A first terminal of the first transistor is configured to be connected to the supply voltage, a second terminal of the first transistor is electrically connected to a first terminal of the first current mirror, a second terminal of the first current mirror is electrically connected to a first terminal of the first voltage-limiting assembly, a second terminal of the first voltage-limiting assembly is electrically connected to the third terminal of the channel selection circuit, a third terminal of the first current mirror is electrically connected to the gate electrode of the switch transistor, and a control terminal of the first transistor is electrically connected between the second terminal of the first voltage-limiting assembly and the third terminal of the channel selection circuit.

The first current mirror is configured to convert the first current to obtain the pull-up current.

The first voltage-limiting assembly is configured to turn on the first transistor to output the pull-up current.

In some embodiments, the first current mirror includes a first N-type transistor and a second N-type transistor.

A first terminal of the first N-type transistor is configured to be connected to the supply voltage or is electrically connected to the second terminal of the first transistor, a control terminal of the first N-type transistor is electrically connected to a control terminal and a first terminal of the second N-type transistor, a second terminal of the first N-type transistor and a second terminal of the second N-type transistor are both electrically connected to the gate electrode of the switch transistor, and the first terminal of the second N-type transistor is further electrically connected to the third terminal of the channel selection circuit or the first terminal of the first voltage-limiting assembly.

In some embodiments, the output pull-down circuit includes a second current mirror.

A first terminal of the second current mirror is electrically connected to the fourth terminal of the channel selection circuit, a second terminal of the second current mirror is electrically connected to the source electrode of the switch transistor, and a third terminal of the second current mirror is electrically connected between the third terminal of the output pull-up circuit and the gate electrode of the switch transistor.

The second current mirror is configured to convert the first current to obtain the pull-down current.

Alternatively, the output pull-down circuit includes a second current mirror, a second transistor, and a second voltage-limiting assembly.

A first terminal of the second voltage-limiting assembly is electrically connected to the fourth terminal of the channel selection circuit, a second terminal of the second voltage-limiting assembly is electrically connected to a first terminal of the second current mirror, a second terminal of the second current mirror is electrically connected to a second terminal of the second transistor, a first terminal of the second transistor is electrically connected between the third terminal of the output pull-up circuit and the gate electrode of the switch transistor, a third terminal of the second current mirror is electrically connected to the source electrode of the switch transistor, and a control terminal of the second transistor is electrically connected between the first terminal of the second voltage-limiting assembly and the fourth terminal of the channel selection circuit.

The second current mirror is configured to convert the first current to obtain the pull-down current.

The second voltage-limiting assembly is configured to turn on the second transistor to output the pull-down current.

In some embodiments, the second current mirror includes a third N-type transistor and a fourth N-type transistor.

A first terminal of the third N-type transistor is electrically connected between the third terminal of the output pull-up circuit and the gate electrode of the switch transistor or is electrically connected to the second terminal of the second transistor, a control terminal of the third N-type transistor is electrically connected to a control terminal and a first terminal of the fourth N-type transistor, a second terminal of the third N-type transistor and a second terminal of the fourth N-type transistor are both electrically connected to the source electrode of the switch transistor, and the first terminal of the fourth N-type transistor is further electrically connected to the fourth terminal of the channel selection circuit or the second terminal of the second voltage-limiting assembly.

In some embodiments, the voltage-limiting assembly includes a diode.

A first terminal of the diode is electrically connected to the second terminal of the first current mirror or the first terminal of the second current mirror, and a second terminal of the diode is electrically connected to the third terminal of the channel selection circuit or the fourth terminal of the channel selection circuit.

Alternatively, the voltage-limiting assembly includes a resistor.

A first terminal of the resistor is electrically connected to the second terminal of the first current mirror or the first terminal of the second current mirror, and a second terminal of the resistor is electrically connected to the third terminal of the channel selection circuit or the fourth terminal of the channel selection circuit.

In some embodiments, the channel selection circuit includes a level conversion circuit, a control circuit, and a channel output circuit.

An input terminal of the level conversion circuit is configured to be connected to the control signal, an output terminal of the level conversion circuit is electrically connected to an input terminal of the control circuit, a first output terminal of the control circuit is electrically connected to a first control terminal of the channel output circuit, a second output terminal of the control circuit is electrically connected to a second control terminal of the channel output circuit, an input terminal of the channel output circuit is electrically connected to the output terminal of the first current output circuit, a first output terminal of the channel output circuit is electrically connected to the first input terminal of the output stage circuit, and a second output terminal of the channel output circuit is electrically connected to the second input terminal of the output stage circuit.

The level conversion circuit is configured to convert the control signal to obtain a converted control signal, and transmit the converted control signal to the control circuit.

The control circuit is configured to obtain a first signal based on the converted control signal, and transmit the first signal to the channel output circuit, the first signal being used for determining whether the transmission channel for the first current is the pull-up channel or the pull-down channel.

The channel output circuit is configured to transmit the first current to the output stage circuit based on the first signal.

In some embodiments, the channel output circuit includes a first P-type transistor and a second P-type transistor.

A second terminal of the first P-type transistor and a second terminal of the second P-type transistor are both electrically connected to the output terminal of the first current output circuit, a control terminal of the first P-type transistor is electrically connected to the second output terminal of the control circuit, a first terminal of the first P-type transistor is electrically connected to the second input terminal of the output stage circuit, a control terminal of the second P-type transistor is electrically connected to the first output terminal of the control circuit, and a first terminal of the second P-type transistor is electrically connected to the first input terminal of the output stage circuit.

In some embodiments, the first current output circuit includes a current generation circuit and a third current mirror.

An input terminal of the current generation circuit is configured to receive a digital signal, an output terminal of the current generation circuit is electrically connected to a first terminal of the third current mirror, and a second terminal of the third current mirror is electrically connected to the first terminal of the channel selection circuit.

The current generation circuit is configured to generate a current corresponding to the digital signal, and transmit the current corresponding to the digital signal to the third current mirror.

The third current mirror is configured to convert the current corresponding to the digital signal to obtain the first current.

In some embodiments, the third current mirror includes a third P-type transistor and a fourth P-type transistor.

A second terminal of the third P-type transistor and a second terminal of the fourth P-type transistor are both configured to be connected to a first voltage, a first terminal of the third P-type transistor is electrically connected to the output terminal of the current generation circuit, a control terminal of the third P-type transistor and a control terminal of the fourth P-type transistor, and a first terminal of the fourth P-type transistor is electrically connected to the first terminal of the channel selection circuit, wherein the first voltage is greater than a source voltage of the switch transistor and the gate voltage of the switch transistor.

In some embodiments, the gate driver circuit further includes a pulse current output circuit and a switch circuit.

A first terminal of the pulse current output circuit is electrically connected to a first terminal of the first current output circuit, a first input terminal of the pulse current output circuit is electrically connected to the first output terminal of the control circuit, a second input terminal of the pulse current output circuit is electrically connected to the second output terminal of the control circuit, an output terminal of the pulse current output circuit is electrically connected between the output terminal of the first current output circuit and the first terminal of the channel selection circuit, a first terminal of the switch circuit is electrically connected between the first output terminal of the control circuit and the first control terminal of the channel output circuit, a second terminal of the switch circuit is electrically connected between the second output terminal of the control circuit and the second control terminal of the channel output circuit, a third terminal of the switch circuit is electrically connected between the first output terminal of the channel output circuit and the first input terminal of the output stage circuit, a fourth terminal of the switch circuit is electrically connected to the gate electrode of the switch transistor, a fifth terminal of the switch circuit is electrically connected between the second output terminal of the channel output circuit and the second input terminal of the output stage circuit, and a sixth terminal of the switch circuit is electrically connected to the source electrode of the switch transistor.

The pulse current output circuit is configured to transmit a pulse current to the first current output circuit to accelerate turn-on of a transistor in the output stage circuit, the pulse current being used for increasing the first current.

The switch circuit is configured to discharge, based on the first signal, a gate parasitic capacitor of the transistor in the output stage circuit to accelerate turn-off of the transistor in the output stage circuit.

In some embodiments, the pulse current output circuit includes a logic assembly, a third P-type transistor, and a current source.

A first input terminal of the logic assembly is electrically connected to the first output terminal of the control circuit, a second input terminal of the logic assembly is electrically connected to the second output terminal of the control circuit, an output terminal of the logic assembly is electrically connected to the control terminal of the third P-type transistor, a second terminal of the third P-type transistor is electrically connected to the first terminal of the first current output circuit via the current source, and a first terminal of the third P-type transistor is electrically connected between the output terminal of the first current output circuit and the first terminal of the channel selection circuit.

The logic assembly is configured to obtain a pulse signal by performing logic processing on the first signal, the pulse signal being used for controlling turn-on of the third P-type transistor.

In some embodiments, the logic assembly includes a first XOR gate device, a second XOR gate device, a first delay device, a second delay device, and a NOR gate device.

A first input terminal of the first XOR gate device is electrically connected to the first output terminal of the control circuit, a second input terminal of the first XOR gate device is electrically connected to an output terminal of the first delay device, an input terminal of the first delay device is electrically connected between the first input terminal of the first XOR gate device and the first output terminal of the control circuit, an output terminal of the first XOR gate device is electrically connected to a first input terminal of the NOR gate device, a first input terminal of the second XOR gate device is electrically connected to the second output terminal of the control circuit, a second input terminal of the second XOR gate device is electrically connected to an output terminal of the second delay device, an input terminal of the second delay device is electrically connected between the first input terminal of the second XOR gate device and the second output terminal of the control circuit, an output terminal of the second XOR gate device is electrically connected to a second input terminal of the NOR gate device, and an output terminal of the NOR gate device is electrically connected to the control terminal of the third P-type transistor.

In some embodiments, the switch circuit includes a first switch assembly, a second switch assembly, a first diode assembly, and a second diode assembly.

A first terminal of the first diode assembly and a control terminal of the first switch assembly are both electrically connected between the first output terminal of the control circuit and the first control terminal of the channel output circuit, a second terminal of the first diode assembly and a second terminal of the first switch assembly are both electrically connected to the source electrode of the switch transistor, a first terminal of the first switch assembly is electrically connected between the second output terminal of the channel output circuit and the second input terminal of the output stage circuit, a first terminal of the second diode assembly and a control terminal of the second switch assembly are both electrically connected between the second output terminal of the control circuit and the second control terminal of the channel output circuit, a second terminal of the second diode assembly and a second terminal of the second switch assembly are both electrically connected to the gate electrode of the switch transistor, and a first terminal of the second switch assembly is electrically connected between the first output terminal of the channel output circuit and the first input terminal of the output stage circuit.

In some embodiments, the third current mirror includes a fourth P-type transistor, a fifth P-type transistor, and a sixth P-type transistor.

A second terminal of the fourth P-type transistor, a second terminal of the fifth P-type transistor, and a second terminal of the sixth P-type transistor are all configured to be connected to a first voltage, a first terminal of the fourth P-type transistor is electrically connected to the output terminal of the current generation circuit, a control terminal of the fourth P-type transistor, a control terminal of the fifth P-type transistor, and a control terminal of the sixth P-type transistor, a first terminal of the fifth P-type transistor is electrically connected to a fifth terminal of the channel selection circuit, a first terminal of the sixth P-type transistor is electrically connected to the first terminal of the channel selection circuit, and a second terminal of the sixth P-type transistor is further electrically connected to the first terminal of the pulse current output circuit.

In some embodiments, the channel selection circuit further includes a seventh P-type transistor and an eighth P-type transistor.

A second terminal of the seventh P-type transistor is electrically connected to the first terminal of the fifth P-type transistor, a control terminal of the seventh P-type transistor is electrically connected between the second output terminal of the control circuit and the second control terminal of the channel selection circuit, a first terminal of the seventh P-type transistor is electrically connected to the first terminal of the second diode assembly, a second terminal of the eighth P-type transistor is electrically connected between the second terminal of the seventh P-type transistor and the first terminal of the fifth P-type transistor, a control terminal of the eighth P-type transistor is electrically connected between the first output terminal of the control circuit and a first control terminal of the channel selection circuit, and a first terminal of the eighth P-type transistor is electrically connected to the first terminal of the first diode assembly.

In a second aspect, the embodiments of the present application provide a chip. The chip includes the gate driver circuit according to the first aspect and any embodiment of the first aspect.

For details about the beneficial effects achieved by the chip according to the second aspect, reference may be made to the beneficial effects achieved by the first aspect or any embodiment of the first aspect, which are not described herein any further.

In a third aspect, the embodiments of the present application provide an electronic device. The electronic device includes the chip according to the second aspect.

### BRIEF DESCRIPTION OF THE DRAWINGS

FIG. 1 illustrates a gate driver circuit according to the related art;

FIG. 2 illustrates another gate driver circuit according to the related art;

FIG. 3 is a schematic structural diagram of a gate driver circuit according to some embodiments of the present application;

FIG. 4 is a schematic structural diagram of another gate driver circuit according to some embodiments of the present application;

FIG. 5 is a schematic structural diagram of another gate driver circuit according to some embodiments of the present application;

FIG. 6 is a schematic structural diagram of another gate driver circuit according to some embodiments of the present application;

FIG. 7 is a schematic structural diagram of another gate driver circuit according to some embodiments of the present application; and

FIG. 8 is a schematic structural diagram of another gate driver circuit according to some embodiments of the present application.

### DETAILED DESCRIPTION

In the present application, the term “at least one” refers to one or more than one, and the term “a plurality of” refers to two or more than two. The term “and/or” is merely an association relationship for describing associated objects, which represents that there may exist three types of relationships, for example, A and/or B may represent three situations: only A exists, both A and B exist, and only B exists, wherein A and B may be single or plural. In addition, the symbol “/” generally represents an “or” relationship between associated objects before and after the symbol. The expression “at least one of the following” or the like expression means any combination of the items or options listed, including a single item or option or any combination of plural items or options listed. For example, at least one of a single a, a single b, and a single c may indicate: the single a, the single b, the single c, a combination of a and b, a combination of a and c, a combination of b and c, or a combination of a, b, and c, wherein each of a, b, and c may be single or plural. In addition, the terms “first,” “second,” and the like are merely for the illustration purpose, and shall not be construed as indicating or implying a relative importance.

In the description of the present application, it should be understood that the terms “central,” “transversal,” “longitudinal,” “upper,” “lower,” “left,” “right,” “front,” “rear,” and the like indicate orientations and position relationships which are based on the illustrations in the accompanying drawings, and these terms are merely for ease and brevity of the description, instead of indicating or implying that the devices or elements shall have a particular orientation and shall be structured and operated based on the particular orientation. Accordingly, these terms shall not be construed as limiting the present application.

In the description of the present application, unless otherwise explicitly specified and defined, the terms “connected,” “coupled,” and derivatives forms thereof shall be understood in a broad sense. For example, the terms “connected,” “coupled,” and derivatives form thereof for depicting the circuit structure, in addition to physical connection, may also be understood as electrical connections or signal connection. The connection, for example, may be direct connection, i.e., the physical connection or, indirect connection via at least one intermediate element as long as the circuit is conducted, or communication between the interiors of two elements. The signal connection, in addition to signal connection via a circuitry, may also be signal connection via a communication medium, for example, radio waves. Persons of ordinary skill in the art may understand specific meanings of the above terms in the present application according to the actual circumstances and contexts.

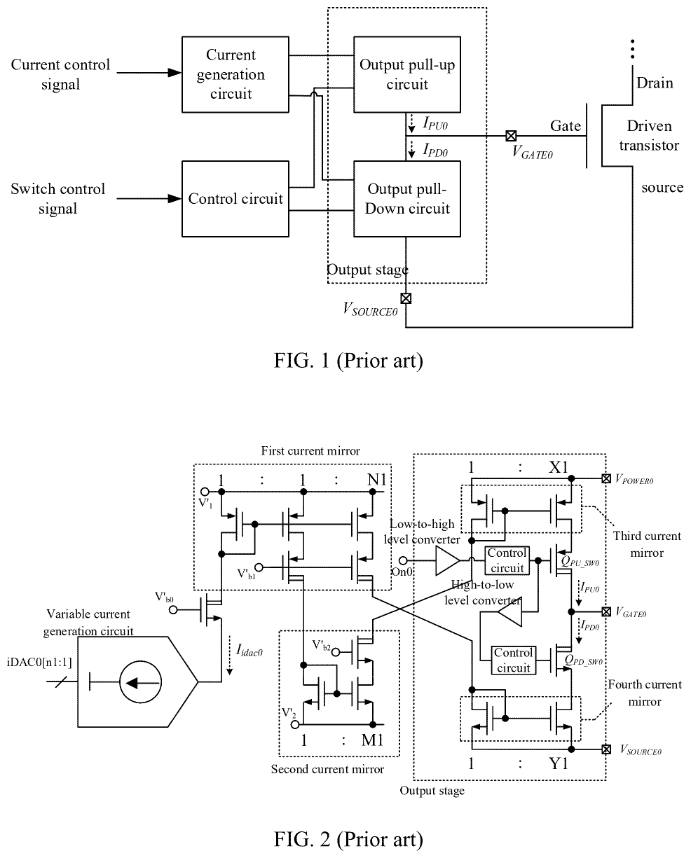

Referring to FIG. 1, FIG. 1 illustrates a gate driver circuit according to the related art. As illustrated in FIG. 1, a current generation circuit generates, based on a current control signal, a current signal serving as a reference current, and transmits the current signal serving as the reference current to an output pull-up circuit and an output pull-down circuit. As such, the output pull-up circuit may generate a pull-up current I_{PU0}, and the output pull-down circuit may generate a pull-down current I_{PD0}. In the meantime, a switch control signal may be converted, via a control circuit, to a first enable signal corresponding to the output pull-up circuit and a second enable signal corresponding to the output pull-down circuit. Hence, under the effect of the first enable signal, the output pull-up circuit outputs a pull-up current I_{PU0}; and under the effect of the second enable signal, the output pull-down circuit outputs a pull-down current I_{PD0}. In this way, the gate driver circuit may charge a gate electrode of a driven transistor using the pull-up current, and discharge the gate electrode of the driven transistor using the pull-down current.

Referring to FIG. 2, FIG. 2 illustrates another gate driver circuit according to the related art. As illustrated in FIG. 2, a variable current generation circuit may generate a current which is equal to I_{idac0} corresponding to a digital signal iDAC0[n1:1], and transmit the current I_{idac0} to a first current mirror, such that the first current mirror may convert the current I_{idac0}. As such, the first current mirror may convert the current I_{idac0} at a ratio of 1:N1 to obtain a converted current which is equal to N1*I_{idac0}, and transmit the converted current N1*I_{idac0} to a fourth current mirror. In this way, the fourth current mirror may convert the converted current N1*I_{idac0} at a conversion ratio of 1:Y1 to obtain a pull-down current I_{PD0} which is equal to Y1*N1*I_{idac0}.

n1 represents the number of bits of the digital signal iDAC0 in the related art, N1 represents a conversion ratio of the first current mirror, and Y1 represents a conversion ratio of the fourth current mirror.

In the meantime, the first current mirror may convert the current at a ratio of 1:1 to obtain a converted current which is equal to I_{idac0}, and transmit the converted current I_{idac0} to a second current mirror. As such, the second current mirror may convert the converted current I_{idac0} at a ratio of 1:M1 to obtain another converted current which is equal to M1*I_{idac}, and transmit the another converted current M1*I_{idac} to a third current mirror. In this way, the third current mirror may convert the another converted current M1*I_{idac} at a conversion ratio of 1:X1 to obtain a pull-up current I_{PU0} which is equal to X1*M1*I_{idac0}.

M1 is a conversion ratio of the second current mirror, and X1 is a conversion ratio of the third current mirror.

The first current mirror is a P-type transistor current mirror, and a source voltage V′1 of the first current mirror is greater than a source voltage V_{SOURCE} of a driven transistor. The second current mirror is an N-type transistor current mirror, and a source voltage V′2 of the second current mirror is lower than a supply voltage V_{POWER0} of the gate driver circuit and the source voltage V′1 of the first current mirror. The third current mirror is a P-type transistor current mirror, and a source voltage of the third current mirror is the supply voltage V_{POWER0} of the gate driver circuit. The fourth current mirror is an N-type transistor current mirror, and a source voltage of the fourth current mirror is the source voltage V_{SOURCE} of the driven transistor.

In addition, a control signal On for controlling pull-up or pull-down of the gate driver circuit is converted, via a low-to-high level converter and the control circuit, to a first gate signal for pulling up the driven transistor. In this way, the first gate signal is converted, via a high-to-low level converter and the control circuit, to a second gate signal for pulling down the driven transistor.

Further, in a case where a control signal On0 is at a high level, that is, the control signal On0 is 1, a pull-up transistor Q_{PU_SW} is turned on, and a pull-down transistor Q_{PD_SW} is turned off. In this case, a gate current I_{GATE} of the driven transistor is the pull-up current, that is, I_{PU0}=X1*M1*I_{idac0}, such that the driven transistor is turned on. It is assumed that a current flowing out of the gate driver circuit is positive.

In a case where the control signal On0 is at a low level, that is, the control signal On0 is 0, the pull-up transistor Q_{PU_SW} is turned off, and the pull-down transistor Q_{PD_SW} is turned on. In this case, the gate current I_{GATE} of the driven transistor is the pull-up current which is negative, that is, I_{PU0}=−Y1*N1*I_{idac0}, such that the driven transistor is turned off.

Since two groups of control circuits, four current mirrors, two level converters, and a P-type transistor as the pull-up transistor Q_{PU_SW} are needed in the gate driver circuit in the related art, and an area of the P-type transistor having the same on-resistance is greater than that of the N-type transistor, such that hardware cost of the gate driver circuit is high. In the meantime, a corresponding voltage source is present inside both the control circuit and the current mirror, and the voltage source has the static power consumption, which leads to a larger power consumption of the gate driver circuit.

In addition, the pull-up current I_{PU0} is obtained by converting the current I_{idac0} via the first current mirror, the second current mirror, and the third current mirror respectively. Since each current mirror has a delay in response to changes of the current I_{idac0}, the gate driver circuit has a slow current response.

Furthermore, in a case where a voltage difference between the supply voltage V_{POWER0} of the gate driver circuit and the source voltage V_{SOURCE} of the driven transistor is greater than a gate-source withstand voltage V_{GSmax} of the driven transistor, that is, a turn-on voltage of the gate driver circuit is greater than the gate-source withstand voltage V_{GSmax} of the driven transistor, a voltage difference between a gate voltage V_{GATE} of the driven transistor and the source voltage V_{SOURCE} of the driven transistor is greater than the gate-source withstand voltage V_{GSmax} of the driven transistor, that is, V_{GATE}−V_{SOURCE}=V_{POWER0}−V_{SOURCE}>V_{GSmax}. V_{GATE} is the gate voltage of the driven transistor, V_{SOURCE} is the source voltage of the driven transistor, V_{POWER} is the supply voltage of the gate driver circuit, and V_{GSmax} is the gate-source withstand voltage of the driven transistor. Consequently, gate oxide of the driven transistor is damaged.

Accordingly, some embodiments of the present application provide a gate driver circuit, a chip, and an electronic device.

In the present application, the gate driver circuit may be a chip or a circuit module.

In the present application, the electronic device may include, but is not limited to, a tablet computer, a router, an industrial robot, and a television.

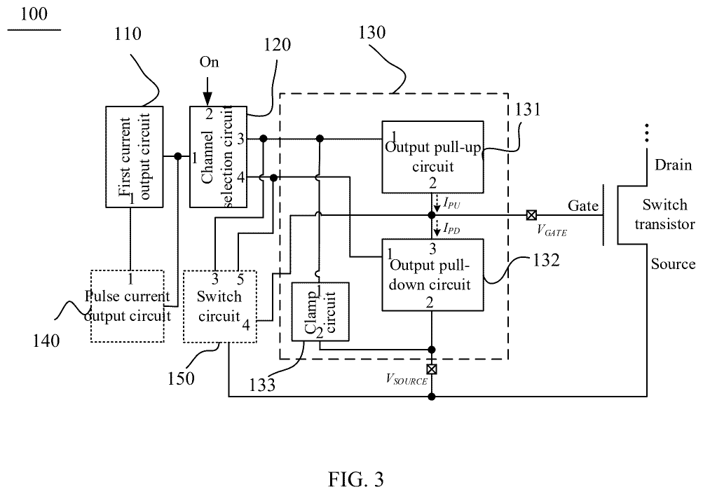

Referring to FIG. 3, FIG. 3 is a schematic structural diagram of a gate driver circuit according to some embodiments of the present application. As illustrated in FIG. 3, the gate driver circuit 100 may include a first current output circuit 110, a channel selection circuit 120, and an output stage circuit 130.

An output terminal of the first current output circuit 110 is electrically connected to a first terminal of the channel selection circuit 120, a second terminal of the channel selection circuit 120 is configured to receive a control signal On, the control signal On being used for controlling the gate driver circuit 100 to drive a switch transistor to be turned on or turned off, a third terminal of the channel selection circuit 120 is electrically connected to a first input terminal of the output stage circuit 130, a fourth terminal of the channel selection circuit 120 is electrically connected to a second input terminal of the output stage circuit 130, and an output terminal of the output stage circuit 130 is electrically connected to a gate electrode of the switch transistor.

One control circuit 122 is provided in the channel selection circuit 120.

The first current output circuit 110, the channel selection circuit 120, and the output stage circuit 130 may be arranged separately, or may be integrated.

In FIG. 3, the first terminal of the channel selection circuit 120 is marked as 1, the second terminal of the channel selection circuit 120 is marked as 2, the third terminal of the channel selection circuit 120 is marked as 3, and the fourth terminal of the channel selection circuit 120 is marked as 4; a first terminal of an output pull-up circuit 131 is marked as 1, and a second terminal of the output pull-up circuit 131 is marked as 2; a first terminal of an output pull-down circuit 132 is marked as 1, and a second terminal of the output pull-down circuit 132 is marked as 2; a first terminal of a clamp circuit 133 is marked as 1, and a second terminal of the clamp circuit 133 is marked as 2; a first terminal of an output pull-up circuit is marked as 1, a first terminal of the first current output circuit 110 is marked as 1, a third terminal of a switch circuit 150 is marked as 3, a fourth terminal of the switch circuit 150 is marked as 4, and a fifth terminal of the switch circuit 150 is marked as 5.

The switch transistor may be a high side switch transistor or a low side switch transistor, which is not specifically limited in the embodiments of the present application. That is, the gate driver circuit 100 may drive the high side switch transistor to be turned on or turned off, or drive the low side switch transistor to be turned on or turned off.

The first current output circuit 110 may transmit a first current to the channel selection circuit 120, such that the channel selection circuit 120 obtains the first current.

The first current serves as a reference current.

The channel selection circuit 120 may select a transmission channel for the first current based on the control signal On. In addition, the channel selection circuit 120 may transmit the first current to the output stage circuit 130 over the transmission channel.

For example, in a case where the control signal On is at a high level, that is, the control signal On is 1, the transmission channel for the first current is a pull-up channel, such that the channel selection circuit 120 may transmit the first current to the output stage circuit 130 over the pull-up channel. Thus, the output stage circuit 130 may convert the first current at a 1:1 ratio, at an enlarged (larger) ratio, or at a reduced (smaller) ratio. That is, by converting the first current, the output stage circuit 130 may obtain a second current. In this way, the output stage circuit 130 may pull up a gate voltage V_{GATE} of the switch transistor using the second current, such that the gate driver circuit 100 may drive the switch transistor to be turned on.

For example, in a case where the control signal On is at a low level, that is, the control signal On is 0, the transmission channel for the first current is a pull-down channel, such that the channel selection circuit 120 transmits the first current to the output stage circuit 130 over the pull-down channel. Thus, the output stage circuit 130 may obtain the second current by converting the first current. In this way, the output stage circuit 130 may pull down the gate voltage V_{GATE} of the switch transistor using the second current, such that the gate driver circuit 100 drives the switch transistor to be turned off.

The second current is used for pulling up or pulling down the gate voltage V_{GATE} of the switch transistor.

Since only one control circuit 122 is arranged in the channel selection circuit 120, the number of hardware in the gate driver circuit 100 is reduced. In this way, a cost of the gate driver circuit 100 is lowered. In addition, since only one control circuit 122 is arranged, the number of voltage sources arranged inside the control circuit 122 is also one. Hence, the static power consumption of the control circuit 122 is reduced, such that the power consumption of the gate driver circuit 100 is reduced. In this way, the cost and power consumption of the gate driver circuit 100 are reduced, such that the cost and power consumption of the electronic device 100 equipped with the gate driver circuit are both lowered.

In the gate driver circuit, the chip, and the electronic device according to the present application, the first current output circuit may transmit the first current serving as the reference current to the channel selection circuit, such that the channel selection circuit obtains the first current. The channel selection circuit may select a transmission channel for the first current based on the control signal for controlling the gate driver circuit to drive the switch transistor to be turned on or turned off, and transmit the first current to the output stage circuit over the transmission channel, such that the output stage circuit is capable of obtaining the first current. Further, the output stage circuit may output the second current based on the first current, and pull up or pull down the gate voltage of the switch transistor using the second current, such that the gate driver circuit may drive the switch transistor to be turned on or turned off. Since one control circuit is provided in the channel selection circuit, hardware in the gate driver circuit is reduced to lower the cost of the gate driver circuit. In addition, since one control circuit is provided, the number of voltage sources arranged inside the control circuit is also one to reduce static power consumption of the control circuit, such that power consumption of the gate driver circuit is reduced. In this way, the cost and power consumption of the gate driver circuit are reduced, such that the cost and power consumption of the electronic device equipped with the gate driver circuit are both reduced.

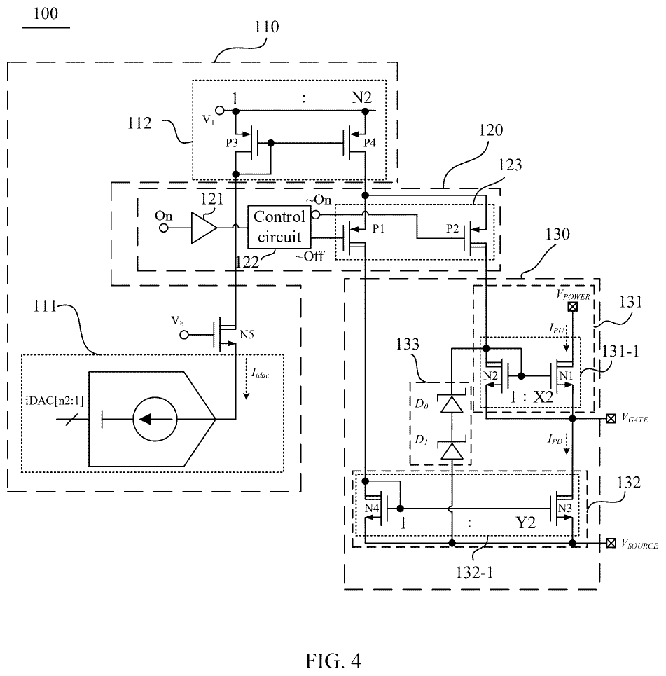

Based on the description of the above embodiment, exemplarily, one possible implementation of the output stage circuit 130 is described hereinafter. Referring to FIG. 4, FIG. 4 is a schematic structural diagram of the output stage circuit in FIG. 3. As illustrated in FIG. 4, the output stage circuit 130 may include an output pull-up circuit 131, an output pull-down circuit 132, and a clamp circuit 133.

A first terminal of the output pull-up circuit 131 is electrically connected to the third terminal of the channel selection circuit 120, a second terminal of the output pull-up circuit 131 is electrically connected to the gate electrode of the switch transistor, a first terminal of the output pull-down circuit 132 is electrically connected to the fourth terminal of the channel selection circuit 120, a second terminal of the output pull-down circuit 132 is electrically connected to a source electrode of the switch transistor, a third terminal of the output pull-down circuit 132 is electrically connected between a third terminal of the output pull-up circuit 131 and the gate electrode of the switch transistor, a first terminal of the clamp circuit 133 is electrically connected between the first terminal of the output pull-up circuit 131 and the third terminal of the channel selection circuit 120, and a second terminal of the clamp circuit 133 is electrically connected between the second terminal of the output pull-down circuit 132 and the source electrode of the switch transistor.

The first terminal of the output pull-up circuit 131 is the first input terminal of the output stage circuit 130, the first terminal of the output pull-down circuit 132 is the second input terminal of the output stage circuit 130, each of the second terminal of the output pull-up circuit 131 and the third terminal of the output pull-down circuit 132 acts as the output terminal of the output stage circuit 130.

In some examples, the clamp circuit 133 may include a diode and/or a Zener diode.

The clamp circuit 133 may be formed by two diodes connected in series, a plurality of diodes connected in series, two Zener diodes connected in series, a plurality of Zener diodes connected in series, or a plurality of diodes and a plurality of Zener diodes that are connected in series, which is not limited in the embodiments of the present application.

In a case where the channel selection circuit 120 transmits the first current to the output stage circuit 130 over the pull-up channel, the output pull-up circuit 131 typically obtain a pull-up current I_{PU} by converting the first current at a ratio of 1:X2. In addition, the output pull-up circuit 131 may transmit the pull-up current I_{PU} to the switch transistor. As such, the output pull-up circuit 131 may pull up the gate voltage VGATE of the switch transistor using the pull-up current I_{PU}, such that the output pull-up circuit 131 is capable of driving the switch transistor to be turned on. In this case, a gate current I_{GATE} of the switch transistor is the pull-up current I_{PU}. In this way, the gate driver circuit 100 may drive the switch transistor to be turned on.

The second current may include the pull-up current I_{PU}, and a pull-down current I_{PD}.

X2 is a conversion ratio of the output pull-up circuit 131, that is, a conversion ratio of the first current mirror 131-1 in the output pull-up circuit 131.

In a case where the channel selection circuit 120 transmits the first current to the output stage circuit 130 over the pull-down channel, the output pull-down circuit 132 typically obtain a pull-down current I_{PD} by converting the first current at a ratio of 1:Y2. In addition, the output pull-down circuit 132 may transmit the pull-down current I_{PD} to the switch transistor. In this way, the output pull-down circuit 132 may pull down the gate voltage V_{GATE} of the switch transistor using the pull-down current I_{PD}, such that the output pull-down circuit 131 is capable of driving the switch transistor to be turned off. In this case, a gate current I_{GATE} of the switch transistor is −I_{PD}. Hence, the gate driver circuit 100 may drive the switch transistor to be turned off.

Y2 represents a conversion ratio of the output pull-down circuit 132, that is, a conversion ratio of the second current mirror 132-1 in the output pull-down circuit 132.

In a case where the channel selection circuit 120 transmits the first current to the output stage circuit 130 over the pull-up channel, and the gate voltage V_{GATE} of the switch transistor is greater than or equal to a predetermined voltage, the clamp circuit 133 may be turned on. The clamp circuit 133 may obtain the first current, such that the first current input to the output pull-up circuit 131 is gradually reduced. As such, the pull-up current IPU is gradually reduced to a predetermined current, such that the clamp circuit 133 is capable of pulling down the pull-up current IPU to the predetermined current. Hence, the gate voltage of the switch transistor no longer increases, such that the clamp circuit 133 may clamp a gate-source voltage of the switch transistor. This ensures that the turn-on voltage of the gate driver circuit 100 is lower than a gate-source withstand voltage of the switch transistor. In this way, the gate driver circuit 100 may be used in applications with higher turn-on voltages, which effectively prevents damages to the gate oxide of the switch transistor.

The predetermined current is, for example, zero, or very close to zero.

Therefore, in a case where the transmission channel is a pull-up channel, the output pull-up circuit may obtain a pull-up current by converting the first current, and transmit the pull-up current to the switch transistor, such that the output pull-up circuit is capable of driving to drive the switch transistor to be turned on. In a case where the transmission channel is a pull-down channel, the output pull-down circuit may obtain a pull-down current by converting the first current, and transmit the pull-down current to the switch transistor, such that the output pull-down circuit is capable of driving the switch transistor to be turned off. Hence, the gate driver circuit is capable of driving the switch transistor to be turned on or turned off. In addition, in a case where the transmission channel is a pull-up channel and the gate voltage of the switch transistor is greater than or equal to a predetermined voltage, the clamp circuit may pull down the pull-up current to a predetermined current to clamp a gate-source voltage of the switch transistor, such that a turn-on voltage of the gate driver circuit is lower than the gate-source withstand voltage of the switch transistor. In this way, the gate driver circuit may be used in applications with higher turn-on voltages, which effectively prevents damages to the gate oxide of the switch transistor.

Based on the description of the above embodiment, exemplarily, another possible implementation of the output pull-up circuit 131 is described hereinafter. As illustrated in FIG. 4, the output pull-up circuit 131 may include a first current mirror 131-1.

A first terminal of the first current mirror 131-1 is configured to be connected to the supply voltage V_{POWER}, a second terminal of the first current mirror 131-1 is electrically connected to the third terminal of the channel selection circuit 120, and a third terminal of the first current mirror 131-1 is electrically connected to the gate electrode of the switch transistor.

The second terminal of the first current mirror 131-1 is the first terminal of the output pull-up circuit 131, and the third terminal of the first current mirror 131-1 is the second terminal of the output pull-up circuit 131.

In a case where the channel selection circuit 120 transmits the first current to the output stage circuit 130 over the pull-up channel, the first current mirror 131-1 may obtain the pull-up current I_{PU} by increasing the first current at a ratio of 1:X2. In this way, the output pull-up circuit 131 is capable of obtaining the pull-up current IPU. It is assumed that the current flowing out of the output stage circuit 130 is positive.

The pull-up current IPU may be calculated using equation (1):

$${I}_{P U} = X 2 * {I}_{1} \qquad ( 1 )$$

I_{PU} represents the pull-up current, X2 represents a conversion ratio of the first current mirror 131-1, and I₁ represents the first current.

Therefore, the pull-up current is obtained by converting the first current via the first current mirror. Hence, the output pull-up circuit is capable of obtaining the pull-up current.

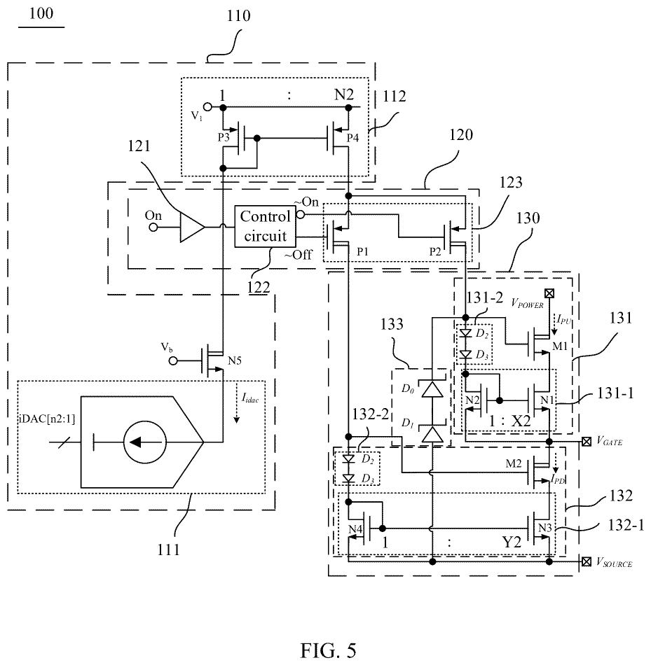

Based on the description of the above embodiments, exemplarily, another possible implementation of the output pull-up circuit 131 is described hereinafter. Referring to FIG. 5, FIG. 5 is a schematic structural diagram of the output stage circuit in FIG. 3. As illustrated in FIG. 5, the output pull-up circuit 131 may include a first current mirror 131-1, a first transistor M1, and a first voltage-limiting assembly 131-2.

A first terminal of the first transistor M1 is configured to be connected to the supply voltage VPOWER, a second terminal of the first transistor M1 is electrically connected to a first terminal of the first current mirror 131-1, a second terminal of the first current mirror 131-1 is electrically connected to a first terminal of the first voltage-limiting assembly 131-2, a second terminal of the first voltage-limiting assembly 131-2 is electrically connected to the third terminal of the channel selection circuit 120, a third terminal of the first current mirror 131-1 is electrically connected to the gate electrode of the switch transistor, and a control terminal of the first transistor M1 is electrically connected between the second terminal of the first voltage-limiting assembly 131-2 and the third terminal of the channel selection circuit 120.

The first transistor M1 serves as a pull-up transistor.

The second terminal of the first voltage-limiting assembly 131-2 is the first terminal of the output pull-up circuit 131, and the third terminal of the first current mirror 131-1 is the second terminal of the output pull-up circuit 131.

In some examples, a withstand voltage of the first transistor M1 is greater than a first predetermined withstand voltage. In this case, the first transistor M1 is a high voltage transistor.

The first transistor M1 is an N-type transistor, which is capable of reducing an area of the first transistor M1. Hence, the cost of the output pull-up circuit 131 is reduced, and the cost of the gate driver circuit 100 is further lowered.

In a case where the channel selection circuit 120 transmits the first current to the output stage circuit 130 over the pull-up channel, since the control terminal of the first transistor M1 is electrically connected between the second terminal of the first voltage-limiting assembly 131-2 and the third terminal of the channel selection circuit 120, under the effect of the first voltage-limiting assembly 131-2, the first transistor M1 is turned on. In the meantime, the first current mirror 131-1 may enlarge the first current at a ratio of 1:X2 to obtain a pull-up current which is equal to I_{PU}. Hence, the output pull-up circuit 131 is capable of obtaining the pull-up current. It is assumed that the current flowing out of the output stage circuit 130 is positive.

In addition, since one first current mirror 131-1 is provided, the number of voltage sources corresponding to the first current mirror 131-1 is also one. In this way, the static power consumption of the voltage source is reduced, such that the power consumption of the output pull-up circuit 131 is lowered. Hence, the power consumption of the gate driver circuit 100 is further reduced.

In addition, since one first current mirror 131-1 is provided, the first current is obtained by converting by the first current mirror 131-1, such that a delay of changes of the first current mirror 131-1 to the first current is reduced. Therefore, the current response speed of the output pull-up circuit 131 is increased. Hence, the current response speed of the gate driver circuit 100 is increased.

In some examples, the first current mirror 131-1 may include a first N-type transistor N1 and a second N-type transistor N2.

A first terminal of the first N-type transistor N1 is configured to be connected to the supply voltage VPOWER or is electrically connected to the second terminal of the first transistor M1, a control terminal of the first N-type transistor N1 is electrically connected to a control terminal and a first terminal of the second N-type transistor N2, a second terminal of the first N-type transistor N1 and a second terminal of the second N-type transistor N2 are both electrically connected to the gate electrode of the switch transistor, and the first terminal of the second N-type transistor N2 is further electrically connected to the third terminal of the channel selection circuit 120 or the first terminal of the first voltage-limiting assembly 131-2.

The first N-type transistor N1 and the second N-type transistor N2 are N-type MOS transistors. The control terminal of the first N-type transistor N1 and the control terminal of the second N-type transistor N2 are both gate electrodes G, the first terminal of the first N-type transistor N1 and the first terminal of the second N-type transistor N2 are both drain electrodes D, and the second terminal of the first N-type transistor N1 and the second terminal of the second N-type transistor N2 are both source electrodes S.

A source voltage of the first current mirror 131-1 is the supply voltage V_{POWER}.

In a case where the output pull-up circuit 131 includes the first current mirror 131-1, an area of the first N-type transistor N1 is smaller, such that the cost of the output pull-up circuit 131 is reduced. Hence, the cost of the gate driver circuit 100 is further lowered. In addition, the first N-type transistor N1 serves as a pull-up transistor.

In a case where the output pull-up circuit 131 includes the first current mirror 131-1, the first transistor M1, and the first voltage-limiting assembly 131-2, a withstand voltage of the first N-type transistor N1 and a withstand voltage of the second N-type transistor N2 are both lower than a second predetermined withstand voltage. In this way, the area of the first N-type transistor N1 and an area of the second N-type transistor N2 are both reduced, such that the cost of the output pull-up circuit 131 is lowered. Hence, the cost of the gate driver circuit 100 is further lowered.

The first transistor M1 is an N-type MOS transistor.

Therefore, under the effect of the first voltage-limiting assembly, the first transistor is turned on. In the meantime, the pull-up current is obtained by converting the first current via the first current mirror. Hence, the output pull-up circuit is capable of obtaining the pull-up current.

Based on the description of the above embodiment, exemplarily, one possible implementation of the output pull-down circuit 132 is described hereinafter. As illustrated in FIG. 4, the output pull-down circuit 132 may include a second current mirror 132-1.

A first terminal of the second current mirror 132-1 is electrically connected to the fourth terminal of the channel selection circuit 120, a second terminal of the second current mirror 132-1 is electrically connected to the source electrode of the switch transistor, and a third terminal of the second current mirror 132-1 is electrically connected between the third terminal of the output pull-up circuit 131 and the gate electrode of the switch transistor.

The first terminal of the second current mirror 132-1 is the first terminal of the output pull-down circuit 132, the second terminal of the second current mirror 132-1 is the second terminal of the output pull-down circuit 132, and the third terminal of the second current mirror 132-1 is the third terminal of the output pull-down circuit 132.

In a case where the channel selection circuit 120 transmits the first current to the output stage circuit 130 over the pull-down channel, the second current mirror 132-1 may obtain the pull-down current I_{PD} by increasing the first current at a ratio of 1:Y2. Hence, the output pull-down circuit 132 is capable of obtaining the pull-down current I_{PD}. It is assumed that the current flowing out of the output stage circuit 130 is positive.

Y2 represents a conversion ratio of the second current mirror 132-1.

The pull-down current I_{PD} may be calculated using equation (2):

$${I}_{P D} = Y 2 * {I}_{1} \qquad ( 2 )$$

I_{PD} represents the pull-down current, Y2 represents the conversion ratio of the second current mirror 132-1, and I₁ represents the first current.

Therefore, the pull-down current is obtained by converting the first current via the second current mirror. Hence, the output pull-down circuit is capable of obtaining the pull-down current.

Based on the description of the above embodiment, exemplarily, another possible implementation of the output pull-down circuit 132 is described hereinafter. As illustrated in FIG. 5, the output pull-down circuit 132 may include a second current mirror 132-1, a second transistor M2, and a second voltage-limiting assembly 132-2.

A first terminal of the second voltage-limiting assembly 132-2 is electrically connected to the fourth terminal of the channel selection circuit 120, a second terminal of the second voltage-limiting assembly 132-2 is electrically connected to a first terminal of the second current mirror 132-1, a second terminal of the second current mirror 132-1 is electrically connected to a second terminal of the second transistor M2, a first terminal of the second transistor M2 is electrically connected between the third terminal of the output pull-up circuit 131 and the gate electrode of the switch transistor, a third terminal of the second current mirror 132-1 is electrically connected to a source electrode of the switch transistor, and a control terminal of the second transistor M2 is electrically connected between the first terminal of the second voltage-limiting assembly 132-2 and the fourth terminal of the channel selection circuit 120.

The second transistor M2 serves as a pull-down transistor. For example, the second transistor M2 is an N-type MOS transistor, the control terminal of the second transistor M2 is a gate electrode G, the first terminal of the second transistor M2 is a drain electrode D, and the second terminal of the second transistor M2 is a source electrode S.

In some examples, a withstand voltage of the second transistor M2 is greater than a third predetermined withstand voltage. In this case, the second transistor M2 is a high voltage transistor.

The first terminal of the second voltage-limiting assembly 132-2 is the first terminal of the output pull-down circuit 132, the third terminal of the second current mirror 132-1 is the second terminal of the output pull-down circuit 132, and the first terminal of the second transistor M2 is the third terminal of the output pull-down circuit 132.

In a case where the channel selection circuit 120 transmits the first current to the output stage circuit 130 over the pull-down channel, since the control terminal of the second transistor M2 is electrically connected between the first terminal of the second voltage-limiting assembly 132-2 and the fourth terminal of the channel selection circuit 120, under the effect of the second voltage-limiting assembly 132-2, the second transistor M2 is turned on. In the meantime, the second current mirror 132-1 may increase the first current at a ratio of 1:Y2 to obtain a pull-down current which is equal to I_{PD}. Hence, the output pull-down circuit 132 is capable of obtaining the pull-down current I_{PD}. It is assumed that the current flowing out of the output stage circuit 130 is positive.

In some examples, the second current mirror 132-1 may include a third N-type transistor N3 and a fourth N-type transistor N4.

A first terminal of the third N-type transistor N3 is electrically connected between the third terminal of the output pull-up circuit 131 and the gate electrode of the switch transistor or is electrically connected to the second terminal of the second transistor M2, a control terminal of the third N-type transistor N3 is electrically connected to a control terminal and a first terminal of the fourth N-type transistor N4, a second terminal of the third N-type transistor N3 and a second terminal of the fourth N-type transistor N4 are both electrically connected to the source electrode of the switch transistor, and the first terminal of the fourth N-type transistor N4 is further electrically connected to the fourth terminal of the channel selection circuit 120 or the second terminal of the second voltage-limiting assembly 132-2.

For example, the third N-type transistor N3 and the fourth N-type transistor N4 are N-type transistors, the control terminal of the third N-type transistor N3 and the control terminal of the fourth N-type transistor N4 are both gate electrodes G, the first terminal of the third N-type transistor N3 and the first terminal of the fourth N-type transistor N4 are both drain electrodes D, and the second terminal of the third N-type transistor N3 and the second terminal of the fourth N-type transistor N4 are both source electrodes S.

A source voltage of the second current mirror 132-1 is a gate voltage V_{GATE} of the switch transistor.

In a case where the output pull-down circuit 132 may include the second current mirror 132-1, the third N-type transistor N3 serves as a pull-down transistor.

Therefore, under the effect of the second voltage-limiting assembly, the second transistor is turned on. In the meantime, the pull-down current is obtained by converting the first current via the second current mirror. Hence, the output pull-down circuit is capable of obtaining the pull-down current.

Based on the description of the above embodiments, exemplarily, one possible implementation of the voltage-limiting assembly is described hereinafter. As illustrated in FIG. 4 and FIG. 5, the voltage-limiting assembly may include a diode D.

A first terminal of the diode D is electrically connected to the second terminal of the first current mirror 131-1 or the first terminal of the second current mirror 132-1, and a second terminal of the diode D is electrically connected to the third terminal of the channel selection circuit 120 or the fourth terminal of the channel selection circuit 120.

The first voltage-limiting assembly 131-2 and the second voltage-limiting assembly 132-2 are both voltage limiting assemblies.

The voltage-limiting assembly, which is the first voltage-limiting assembly 131-2 or the second voltage-limiting assembly 132-2, may be formed by two diodes connected in series, a plurality of diodes connected in series, two Zener diodes connected in series, a plurality of Zener diodes connected in series, or a plurality of diodes and a plurality of Zener diodes that are connected in series, which is not limited in the embodiments of the present application.

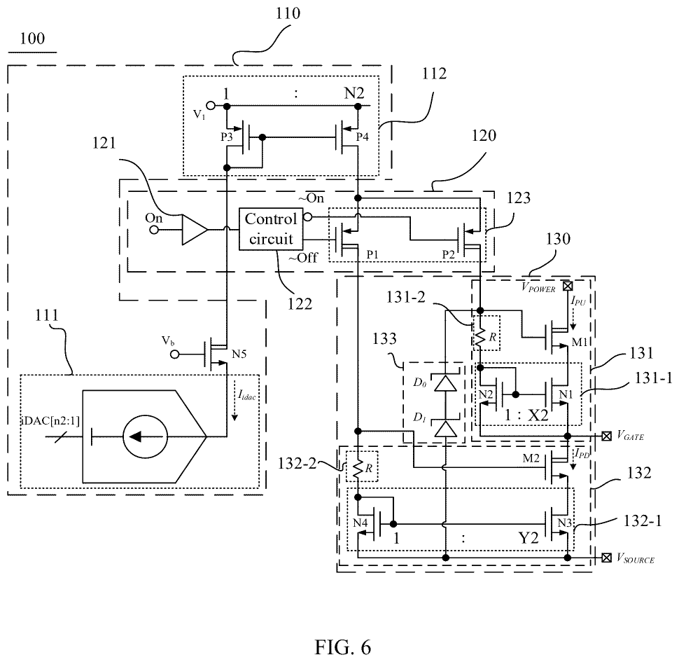

Based on the description of the above embodiments, exemplarily, another possible implementation of the voltage-limiting assembly is described hereinafter. Referring to FIG. 6, FIG. 6 is a schematic structural diagram of the output stage circuit in FIG. 3. As illustrated in FIG. 6, the voltage-limiting assembly may include a resistor R.

A first terminal of the resistor R is electrically connected to the second terminal of the first current mirror 131-1 or the first terminal of the second current mirror 132-1, and a second terminal of the resistor R is electrically connected to the third terminal of the channel selection circuit 120 or the fourth terminal of the channel selection circuit 120.

Based on the description of the above embodiment, exemplarily, one possible implementation of the channel selection circuit 120 is described hereinafter. As illustrated in FIG. 4 to FIG. 6, the channel selection circuit 120 may include a level conversion circuit 121, a control circuit 122, and a channel output circuit 123.

An input terminal of the level conversion circuit 121 is configured to be connected to the control signal On, an output terminal of the level conversion circuit 121 is electrically connected to an input terminal of the control circuit 122, a first output terminal of the control circuit 122 is electrically connected to a first control terminal of the channel output circuit 123, a second output of the control circuit 122 is electrically connected to a second control terminal of the channel output circuit 123, an input terminal of the channel output circuit 123 is electrically connected to the output terminal of the first current output circuit 110, a first output terminal of the channel output circuit 123 is electrically connected to the first input terminal of the output stage circuit 130, and a second output terminal of the channel output circuit 123 is electrically connected to the second input terminal of the output stage circuit 130.

The input terminal of the channel output circuit 123 is the first terminal of the channel selection circuit 120, the input terminal of the level conversion circuit 121 is the second terminal of the channel selection circuit 120, the first output terminal of the channel output circuit 123 is the third terminal of the channel selection circuit 120, and the second output terminal of the channel output circuit 123 is the fourth terminal of the channel selection circuit 120.

The level conversion circuit 121 may convert the control signal On to obtain a converted control signal On. The level conversion circuit 121 may transmit the converted control signal On to the control circuit 122.

The level conversion circuit 121 is generally a low-to-high level converter. Generally, the control signal On is within a first voltage domain and the converted control signal On is within a second voltage domain. The voltage of the first voltage domain is lower than the voltage of the second voltage domain. That is, the level in the first voltage domain is a low level, and the level in the second voltage domain is a high level.

In this way, the control circuit 122 may obtain a first signal based on the converted control signal On. In addition, the control circuit 122 may transmit the first signal to the channel output circuit 123.

The first signal is used for determining whether the transmission channel for the first current is the pull-up channel or the pull-down channel.

The first signal may include a first sub-signal On and a second sub-signal Off.

In a case where the control signal On is at a high level, that is, the control signal On is 1, the first sub-signal On is at a low level, and the second sub-signal Off is at a high level. In this way, it is determined, based on the first signal, that the transmission channel for the first current is the pull-up channel. In a case where the control signal On is at a low level, that is, the control signal On is 1, the first sub-signal On is at a high level, and the second sub-signal Off is at a low level. In this way, it is determined, based on the first signal, that the transmission channel for the first current is the pull-down channel.

Hence, the channel output circuit 123 may transmit the first current to the output stage circuit 130 based on the first signal.

In a case where it is determined, based on the first signal, that the transmission channel for the first current is the pull-up channel, the channel output circuit 123 may transmit the first current to the output stage circuit 130, such that the output stage circuit 130 is capable of outputting the pull-up current I_{PU}. In this way, the output stage circuit 130 is capable of driving the switch transistor to be turned on. In a case where it is determined, based on the first signal, that the transmission channel for the first current is the pull-down channel, the channel output circuit 123 may transmit the first current to the output stage circuit 130, such that the output stage circuit 130 is capable of outputting the pull-down current I_{PD}. In this way, the output stage circuit 130 is capable of driving the switch transistor to be turned off.

In addition, only one level conversion circuit 121 is provided, such that the hardware cost of the channel selection circuit 120 is reduced. Hence, the cost of the gate driver circuit 100 is further lowered. In this way, the cost of the gate driver circuit 100 is greatly lowered.

Therefore, the level conversion circuit may convert the control signal to obtain a converted control signal, and transmit the converted control signal to the control circuit, such that the control circuit is capable of obtaining the converted control signal. As such, the control circuit may obtain, based on converted control signal, the first signal for determining whether the transmission channel for the first current is the pull-up channel or the pull-down channel, and transmit the first signal to the channel output circuit, such that the channel output circuit is capable of obtaining the first signal. Further, the channel output circuit may transmit the first current to the output stage circuit based on the first signal. Hence, the output stage circuit is capable of obtaining the second current to drive the switch transistor to be turned on or turned off.

Based on the description of the above embodiment, exemplarily, one possible implementation of the channel output circuit 123 is described hereinafter. As illustrated in FIG. 4 to FIG. 6, the channel output circuit 123 may include a first P-type transistor P1 and a second P-type transistor P2.

A second terminal of the first P-type transistor P1 and a second terminal of the second P-type transistor P2 are both electrically connected to the output terminal of the first current output circuit 110, a control terminal of the first P-type transistor P1 is electrically connected to the second output terminal of the control circuit 122, a first terminal of the first P-type transistor P1 is electrically connected to the second input terminal of the output stage circuit 130, a control terminal of the second P-type transistor P2 is electrically connected to the first output terminal of the control circuit 122, and a first terminal of the second P-type transistor P2 is electrically connected to the first input terminal of the output stage circuit 130.

The first P-type transistor P1 and the second P-type transistor P2 are both P-type MOS transistors, the control terminal of the first P-type transistor P1 and the control terminal of the second P-type transistor P2 are both gate electrodes G, the first terminal of the first P-type transistor P1 and the first terminal of the second P-type transistor P2 are both drain electrodes D, and the second terminal of the first P-type transistor P1 and the second terminal of the second P-type transistor P2 are both source electrodes S.

In some examples, a withstand voltage of the first P-type transistor P1 and a withstand voltage of the second P-type transistor P2 are both greater than a fourth predetermined withstand voltage. In this case, the first P-type transistor P1 and the second P-type transistor P2 are both high-voltage transistors.

In a case where it is determined, based on the first signal, that the transmission channel for the first current is the pull-up channel, the first P-type transistor P1 is turned off and the second P-type transistor P2 is turned on, such that the first current is input into the first input terminal of the output stage circuit 130 via the second P-type transistor P2. Hence, the transmission channel for the first current is the pull-up channel, such that the output stage circuit 130 is capable of driving the switch transistor to be turned on.

In a case where it is determined, based on the first signal, that the transmission channel for the first current is the pull-down channel, the first P-type transistor P1 is turned on and the second P-type transistor P2 is turned off, such that the first current is input into the second input terminal of the output stage circuit 130 via the first P-type transistor P1. Hence, the transmission channel for the first current is the pull-down channel, such that the output stage circuit 130 is capable of driving the switch transistor to be turned off.

Therefore, in a case where it is determined, based on the first signal, that the transmission channel for the first current is the pull-up channel, the first P-type transistor is turned off and the second P-type transistor is turned on, such that the transmission channel for the first current is the pull-up channel. In a case where it is determined, based on the first signal, that the transmission channel for the first current is the pull-down channel, the first P-type transistor is turned on and the second P-type transistor is turned off, such that the transmission channel for the first current is the pull-down channel. In this way, the channel selection circuit is capable of selecting the transmission channel for the first current as the pull-up channel or the pull-down channel.

Based on the description of the above embodiment, exemplarily, one possible implementation of the first current output circuit 110 is described hereinafter. As illustrated in FIG. 4 to FIG. 6, the first current output circuit 110 may include a current generation circuit 111 and a third current mirror 112.

An input terminal of the current generation circuit 111 is configured to be connected to a digital signal iDAC[n2:1], an output terminal of the current generation circuit 111 is electrically connected to a first terminal of the third current mirror 112, and a second terminal of the third current mirror 112 is electrically connected to the first terminal of the channel selection circuit 120.

The current generation circuit 111 is generally a current-type digital-to-analog converter. n2 represents the number of bits of the digital signal iDAC.

In some examples, the third current mirror 112 may include a third P-type transistor P3 and a fourth P-type transistor P4.

A second terminal of the third P-type transistor P3 and a second terminal of the fourth P-type transistor P4 are both configured to be connected to a first voltage V1, a first terminal of the third P-type transistor P3 is electrically connected to the output terminal of the current generation circuit 111, a control terminal of the third P-type transistor P3 and a control terminal of the fourth P-type transistor P4, and a first terminal of the fourth P-type transistor P4 is electrically connected to the first terminal of the channel selection circuit 120.

The third P-type transistor P3 and the fourth P-type transistor P4 are both P-type MOS transistors, the first terminal of the third P-type transistor P3 and the first terminal of the fourth P-type transistor P4 are both drain electrodes D, and the second terminal of the third P-type transistor P3 and the second terminal of the fourth P-type transistor P4 are both source electrodes S.

The first voltage V1 is greater than the source voltage and the gate voltage V_{GATE} of the switch transistor. That is, the source voltage of the third current mirror 112 is the first voltage V1.

The current generation circuit 111 may generate a current I_{idac} corresponding to the digital signal iDAC[n2:1]. In addition, the current generation circuit 111 may transmit the current I_{idac} corresponding to the digital signal iDAC[n2:1] to the third current mirror 112, such that the third current mirror 112 obtains the current I_{idac} corresponding to the digital signal iDAC[n2:1].

In a case where a value of the digital signal iDAC[n2:1] becomes larger, the current I_{idac} corresponding to the digital signal iDAC[n2:1] becomes larger. In a case where the digital signal iDAC[n2:1] becomes smaller, the current I_{idac} corresponding to the digital signal iDAC[n2:1] becomes smaller. That is, the current I_{idac} corresponding to the digital signal iDAC[n2:1] is variable.

In this way, the third current mirror 112 may convert the current I_{idac} corresponding to the digital signal iDAC[n2:1] at a conversion ratio of 1:N2 to obtain the first current. Hence, the first current output circuit 110 may obtain the first current.

The first current may be calculated using equation (3):

$${I}_{1} = N 2 * {I}_{idac} \qquad ( 3 )$$

I₁ represents the first current, N2 represents a conversion ratio of the third current mirror 112, and I_{idac} represents the current corresponding to the digital signal iDAC[n2:1].

Therefore, the current generation circuit may generate a current corresponding to the digital signal, and transmit the current corresponding to the digital signal to the third current mirror, such that the third current mirror is capable of obtaining the current corresponding to the digital signal. In this way, the third current mirror may convert the current corresponding to the digital signal to obtain the first current. Hence, the first current output circuit 110 may obtain the first current.

Based on the description of the above embodiment, exemplarily, another possible implementation of the first current output circuit 110 is described hereinafter. As illustrated in FIG. 4 to FIG. 6, the first current output circuit 110 may further include a fifth N-type transistor N5.

A second terminal of the fifth N-type transistor N5 is electrically connected to the output terminal of the current generation circuit 111, a control terminal of the fifth N-type transistor N5 is configured to be connected to a bias voltage Vb, and a first terminal of the fifth N-type transistor N5 is electrically connected to the first terminal of the third current mirror 112.

The fifth N-type transistor N5 is an N-type transistor, the first terminal of the fifth N-type transistor N5 is a drain electrode D, and the second terminal of the fifth N-type transistor N5 is a source electrode S.

In some examples, a withstand voltage of the fifth N-type transistor N5 is greater than a fifth predetermined withstand voltage. In this case, the fifth N-type transistor N5 is a high voltage transistor. Further, in a case where the P-type transistor in the third current mirror 112 is a low voltage transistor, since the fifth N-type transistor N5 is a high voltage transistor, the P-type transistor in the third current mirror 112 is prevented from damages. Hence, the third current mirror 112 is capable of normally operating.

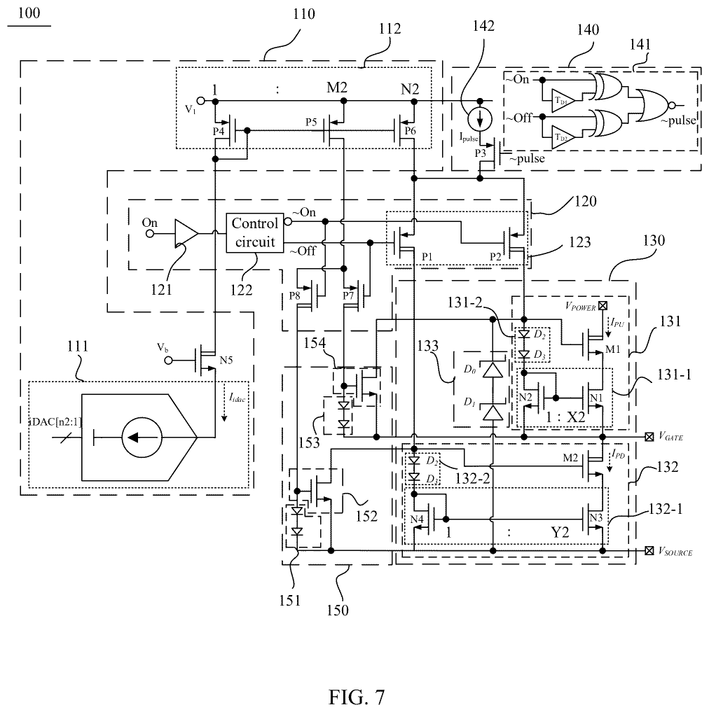

Based on the description of the above embodiment, exemplarily, one possible implementation of the gate driver circuit 100 is described hereinafter. FIG. 7 illustrates the schematic structural diagram of the gate driver circuit in FIG. 3. As illustrated in FIG. 3 and FIG. 7, the gate driver circuit 100 may further include a pulse current output circuit 140 and the switch circuit 150.

A first terminal of the pulse current output circuit 140 is electrically connected to a first terminal of the first current output circuit 110, a first input terminal of the pulse current output circuit 140 is electrically connected to the first output terminal of the control circuit 122, a second input terminal of the pulse current output circuit 140 is electrically connected to the second output terminal of the control circuit 122, an output terminal of the pulse current output circuit 140 is electrically connected between the output terminal of the first current output circuit 110 and the first terminal of the channel selection circuit 120, a first terminal of the switch circuit 150 is electrically connected between the first output terminal of the control circuit 122 and the first control terminal of the channel output circuit 123, a second terminal of the switch circuit 150 is electrically connected between the second output terminal of the control circuit 122 and the second control terminal of the channel output circuit 123, a third terminal of the switch circuit 150 is electrically connected between the first output terminal of the channel output circuit 123 and the first input terminal of the output stage circuit 130, a fourth terminal of the switch circuit 150 is electrically connected to the gate electrode of the switch transistor, a fifth terminal of the switch circuit 150 is electrically connected between the second output terminal of the channel output circuit 123 and the second input terminal of the output stage circuit 130, and a sixth terminal of the switch circuit 150 is electrically connected to the source electrode of the switch transistor.

In a case where the control signal On is at a high level, at a rising edge of the control signal On, the pulse current output circuit 140 transmits a pulse current Iₚᵤₗₛₑ to the first current output circuit 110, such that the first current is increased. In this way, in a case where the current I_{idac} corresponding to the digital signal iDAC[n2:1] is smaller, the gate parasitic capacitor of the pull-up transistor can be quickly fully charged, such that the turn-on of the pull-up transistor is accelerated. In the meantime, since the first sub-signal On is at a low level, and the second sub-signal Off is at a high level, the discharge of a gate parasitic capacitor of the pull-down transistor is accelerated to speed up turn-off of the pull-down transistor. Hence, the gate driver circuit 100 quickly drives the switch transistor to be turned on.

The pulse current Iₚᵤₗₛₑ is used for increasing the first current. Generally, the pulse current Iₚᵤₗₛₑ has a length of T_{D}.

In a case where the control signal On is at a low level, at a falling edge of the control signal On, the pulse current output circuit 140 transmits the pulse current Iₚᵤₗₛₑ to the first current output circuit 110, such that the first current is increased. In this way, in a case where the current I_{idac} corresponding to the digital signal iDAC[n2:1] is smaller, the gate parasitic capacitor of the pull-down transistor can be quickly fully charged, such that the turn-on of the pull-down transistor is accelerated. In the meantime, since the first sub-signal On is at a high level, and the second sub-signal Off is at a low level, the discharge of a gate parasitic capacitor of the pull-up transistor is accelerated to speed up turn-off of the pull-up transistor. Hence, the gate driver circuit 100 quickly drives the switch transistor to be turned on.

Therefore, the pulse current output circuit may transmit the pulse current to the first current output circuit, such that the first current is increased. In this way, the gate parasitic capacitor of the transistor in the output stage circuit is quickly fully charged, such that the turn-on of the transistor in the output stage circuit is accelerated. The switch circuit may discharge, based on the first signal, a gate parasitic capacitor of the transistor in the output stage circuit to accelerate turn-off of the transistor in the output stage circuit. Hence, the gate driver circuit quickly drives the switch transistor to be turned on or turned off. In this way, the gate driver circuit is applicable to a scenario where a switch transistor with a large gate oxide capacitance is used or a switch transistor needs to be quickly turned on or turned off.

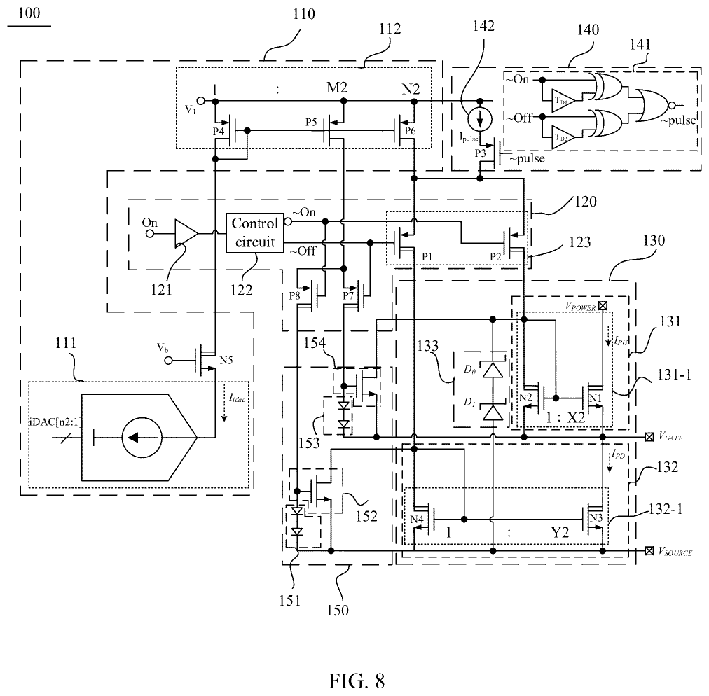

Based on the description of the above embodiments, exemplarily, one possible implementation of the pulse current output circuit 140 is described hereinafter. FIG. 8 illustrates the schematic structural diagram of the gate driver circuit in FIG. 3. As illustrated in FIG. 7 and FIG. 8, the pulse current output circuit 140 may include a logic assembly 141, a third P-type transistor P3, and a current source 142.

A first input terminal of the logic assembly 141 is electrically connected to the first output terminal of the control circuit 122, a second input terminal of the logic assembly 141 is electrically connected to the second output terminal of the control circuit 122, an output terminal of the logic assembly 141 is electrically connected to the control terminal of the third P-type transistor P3, a second terminal of the third P-type transistor P3 is electrically connected to the first terminal of the first current output circuit 110 via the current source 142, and a first terminal of the third P-type transistor P3 is electrically connected between the output terminal of the first current output circuit 110 and the first terminal of the channel selection circuit 120.

The third P-type transistor P3 is a P-type MOS transistor, the control terminal of the third P-type transistor P3 is a gate electrode G, the first terminal of the third P-type transistor P3 is a drain electrode D, and the second terminal of third P-type transistor P3 is a source electrode S.

In addition, FIG. 8 illustrates a schematic structural diagram of the gate driver circuit 100 in a case where the output pull-up circuit 131 includes the first current mirror 131-1.

The first input terminal of the logic assembly 141 is the first input terminal of the pulse current output circuit 140, the second input terminal of the logic assembly 141 is the second input terminal of the pulse current output circuit 140, and the first terminal of the third P-type transistor P3 is the output terminal of the pulse current output circuit 140.

In some examples, the logic assembly 141 may include a first XOR gate device, a second XOR gate device, a first delay device, a second delay device, and a NOR gate device.

A first input terminal of the first XOR gate device is electrically connected to the first output terminal of the control circuit 122, a second input terminal of the first XOR gate device is electrically connected to an output terminal of the first delay device, an input terminal of the first delay device is electrically connected between the first input terminal of the first XOR gate device and the first output terminal of the control circuit 122, an output terminal of the first XOR gate device is electrically connected to a first input terminal of the NOR gate device, a first input terminal of the second XOR gate device is electrically connected to the second output terminal of the control circuit 122, a second input terminal of the second XOR gate device is electrically connected to an output terminal of the second delay device, an input terminal of the second delay device is electrically connected between the first input terminal of the second XOR gate device and the second output terminal of the control circuit 122, an output terminal of the second XOR gate device is electrically connected to a second input terminal of the NOR gate device, or an output terminal of the NOR gate device is electrically connected to the control terminal of the third P-type transistor P3.

The logic assembly 141 may obtain a pulse signal pulse by logically processing the first signal. Under the effect of the pulse signal pulse, the third P-type transistor P3 is turned on, such that the current source 142 transmits the pulse signal pulse to the first current output circuit 110. Hence, the pulse current output circuit 140 transmits the pulse current Iₚᵤₗₛₑ to the first current output circuit 110, such that the first current is increased.

The pulse signal pulse is used for controlling turn-on of the third P-type transistor P3.

In addition, since no new current mirror or level converter is introduced to the pulse current output circuit 140, and the pulse current output circuit share the voltage source with the control circuit 122, the cost and power consumption of the gate driver circuit 100 are reduced.

Therefore, the logic assembly may obtain a pulse signal by performing logic processing on the first signal, such that the third P-type transistor is turned on. In this way, the current source may transmit the pulse current to the first current output circuit. Hence, the pulse current output circuit is capable of transmitting the pulse current to the first current output circuit.

Based on the description of the above embodiment, exemplarily, one possible implementation of the switch circuit 150 is described hereinafter. As illustrated in FIG. 7 and FIG. 8, the switch circuit 150 may include a first switch assembly 152, a second switch assembly 154, a first diode assembly 151, and a second diode assembly 153.

A first terminal of the first diode assembly 151 and a control terminal of the first switch assembly 152 are both electrically connected between the first output terminal of the control circuit 122 and the first control terminal of the channel output circuit 123, a second terminal of the first diode assembly 151 and a second terminal of the first switch assembly 152 are both electrically connected to the source electrode of the switch transistor, a first terminal of the first switch assembly 152 is electrically connected between the second output terminal of the channel output circuit 123 and the second input terminal of the output stage circuit 130, a first terminal of the second diode assembly 153 and a control terminal of the second switch assembly 154 are both electrically connected between the second output terminal of the control circuit 122 and the second control terminal of the channel output circuit 123, a second terminal of the second diode assembly 153 and a second terminal of the second switch assembly 154 are both electrically connected to the gate electrode of the switch transistor, and a first terminal of the second switch assembly 154 is electrically connected between the first output terminal of the channel output circuit 123 and the first input terminal of the output stage circuit 130.

In some examples, each of the first diode assembly 151 and the second diode assembly 153 may include diodes and/or Zener diodes.

Each of the first diode assembly 151 and the second diode assembly 153 may be formed by two diodes connected in series, a plurality of diodes connected in series, two Zener diodes connected in series, a plurality of Zener diodes connected in series, or a plurality of diodes and a plurality of Zener diodes that are connected in series, which is not limited in the embodiments of the present application.

In a case where the first sub-signal On is at a low level, and the second sub-signal Off is at a high level, the first diode assembly 151 is turned on, such that the first switch assembly 152 is turned on. In this way, the discharge of the gate parasitic capacitor of the pull-down transistor is accelerated. Hence, the first switch assembly 152 speeds up turn-off of the pull-down transistor, such that the switch circuit 150 speeds up turn-off of the pull-down transistor.

In a case where the first sub-signal On is at a high level, and the second sub-signal Off is at a low level, the second diode assembly 153 is turned on to cause the second switch assembly 154 to be turned on. In this way, the discharge of the gate parasitic capacitor of the pull-up transistor is accelerated. Hence, the second switch assembly 154 speeds up turn-off of the pull-down transistor, such that the switch circuit 150 speeds up turn-off of the pull-up transistor.

Hence, the switch circuit 150 speeds up turn-off of the transistor in the output stage circuit 130.

In addition, since no new current mirror and level converter are introduced into the switch circuit 150, the cost of the gate driver circuit 100 is lowered.

Therefore, in a case where the first diode assembly is turned on, the first switch assembly is turned on, and hence, turn-off of the pull-down transistor is sped up. In a case where the second diode assembly is turned on, the second switch assembly is turned on, and hence, turn-off of the pull-up transistor is sped up. Hence, the switch circuit is capable of speeding up turn-off of the transistor in the output stage circuit.

Based on the description of the above embodiment, exemplarily, another possible implementation of the third current mirror 112 is described hereinafter. As illustrated in FIG. 7 and FIG. 8, the third current mirror 112 may include a fourth P-type transistor P4, a fifth P-type transistor P5, and a sixth P-type transistor P6.

A second terminal of the fourth P-type transistor P4, a second terminal of the fifth P-type transistor P5, and a second terminal of the sixth P-type transistor P6 are all configured to be connected to a first voltage V1, a first terminal of the fourth P-type transistor P4 is electrically connected to the output terminal of the current generation circuit 111, a control terminal of the fourth P-type transistor P4, a control terminal of the fifth P-type transistor P5, and a control terminal of the sixth P-type transistor P6, a first terminal of the fifth P-type transistor P5 is electrically connected to a fifth terminal of the channel selection circuit 120, a first terminal of the sixth P-type transistor P6 is electrically connected to the first terminal of the channel selection circuit 120, and a second terminal of the sixth P-type transistor P6 is further electrically connected to the first terminal of the pulse current output circuit 140.

The fourth P-type transistor P4, the fifth P-type transistor P5, and the sixth P-type transistor P6 are all P-type MOS transistors, the control terminal of the fourth P-type transistor P4, the control terminal of the fifth P-type transistor P5, and the control terminal of the sixth P-type transistor P6 are all gate electrodes G, the first terminal of the fourth P-type transistor P4, the first terminal of the fifth P-type transistor P5, and the first terminal of the sixth P-type transistor P6 are all drain electrodes D, and the second terminal of the fourth P-type transistor P4, the second terminal of the fifth P-type transistor P5, and the second terminal of the sixth P-type transistor P6 are all source electrodes S.

In some examples, the channel selection circuit 120 may further include a seventh P-type transistor P7 and an eighth P-type transistor P8.

A second terminal of the seventh P-type transistor P7 is electrically connected to the first terminal of the fifth P-type transistor P5, a control terminal of the seventh P-type transistor P7 is electrically connected between the second output terminal of the control circuit 122 and the second control terminal of the channel selection circuit 120, a first terminal of the seventh P-type transistor P7 is electrically connected to the first terminal of the second diode assembly 153, a second terminal of the eighth P-type transistor P8 is electrically connected between the second terminal of the seventh P-type transistor P7 and the first terminal of the fifth P-type transistor P5, a control terminal of the eighth P-type transistor P8 is electrically connected between the first output terminal of the control circuit 122 and a first control terminal of the channel selection circuit 120, and a first terminal of the eighth P-type transistor P8 is electrically connected to the first terminal of the first diode assembly 151.

The seventh P-type transistor P7 and the eighth P-type transistor P8 are both P-type MOS transistors, the control terminal of the seventh P-type transistor P7 and the control terminal of the eighth P-type transistor P8 are both gate electrodes G, the first terminal of the seventh P-type transistor P7 and the first terminal of the eighth P-type transistor P8 are both drain electrodes D, and the second terminal of the seventh P-type transistor P7 and the second terminal of the eighth P-type transistor P8 are both source electrodes S.

After the third current mirror 112 obtains the current I_{idac} corresponding to the digital signal iDAC[n2:1], the third current mirror 112 may convert the current I_{idac} corresponding to the digital signal iDAC[n2:1] at a ratio of 1:M2 via the fifth P-type transistor P5 to obtain a converted current which is equal to M2*I_{idac}.

M2 represents a conversion ratio of the fifth P-type transistor P5.

In a case where the first sub-signal On is at a low level, and the second sub-signal Off is at a high level, the seventh P-type transistor P7 is turned off, and the eighth P-type transistor P8 is turned on. In this way, the first diode assembly 151 is turned on, such that the converted current M2*I_{idac} pulls down a voltage at the control terminal of the first switch assembly 152. Hence, the first switch assembly 152 is turned on, such that the first switch assembly 152 speeds up turn-off of the pull-down transistor.

In a case where the first sub-signal On is at a high level, and the second sub-signal Off is at a low level, the seventh P-type transistor P7 is turned on, and the eighth P-type transistor P8 is turned off. In this way, the second diode assembly 153 is turned on, such that the converted current M2*I_{idac} pulls down a voltage at the control terminal of the second switch assembly 154. Hence, the second switch assembly 154 is turned on, such that the second switch assembly 154 speeds up turn-off of the pull-up transistor.

It should be finally noted that the above embodiments are used only for illustrating the present application, but are not intended to limit the protection scope of the present application. Various modifications and replacements readily derived by those skilled in the art within technical disclosure of the present application shall fall within the protection scope of the present application. Therefore, the protection scope of the present application is subject to the appended claims.

What is claimed is:

1. A gate driver circuit, comprising: a first current output circuit, a channel selection circuit, and an output stage circuit; wherein
an output terminal of the first current output circuit is electrically connected to a first terminal of the channel selection circuit, a second terminal of the channel selection circuit is configured to receive a control signal, the control signal being used for controlling the gate driver circuit to drive a switch transistor to be turned on or turned off, a third terminal of the channel selection circuit is electrically connected to a first input terminal of the output stage circuit, a fourth terminal of the channel selection circuit is electrically connected to a second input terminal of the output stage circuit, and an output terminal of the output stage circuit is electrically connected to a gate electrode of the switch transistor, wherein one control circuit is arranged in the channel selection circuit;
the first current output circuit is configured to transmit a first current to the channel selection circuit, the first current serving as a reference current;
the channel selection circuit is configured to select a transmission channel for the first current based on the control signal, and transmit the first current to the output stage circuit over the transmission channel; and
the output stage circuit is configured to output a second current based on the first current to drive the switch transistor to be turned on or turned off, the second current being used for pulling up or pulling down a gate voltage of the switch transistor.

2. The gate driver circuit according to claim 1, wherein the output stage circuit comprises an output pull-up circuit, an output pull-down circuit, and a clamp circuit; wherein
a first terminal of the output pull-up circuit is electrically connected to the third terminal of the channel selection circuit, a second terminal of the output pull-up circuit is electrically connected to the gate electrode of the switch transistor, a first terminal of the output pull-down circuit is electrically connected to the fourth terminal of the channel selection circuit, a second terminal of the output pull-down circuit is electrically connected to a source electrode of the switch transistor, a third terminal of the output pull-down circuit is electrically connected between a third terminal of the output pull-up circuit and the gate electrode of the switch transistor, a first terminal of the clamp circuit is electrically connected between the first terminal of the output pull-up circuit and the third terminal of the channel selection circuit, and a second terminal of the clamp circuit is electrically connected between the second terminal of the output pull-down circuit and the source electrode of the switch transistor;
the output pull-up circuit is configured to, in a case where the transmission channel is a pull-up channel, convert the first current to obtain a pull-up current, and transmit the pull-up current to the switch transistor to drive the switch transistor to be turned on, wherein the pull-up current is the second current;
the output pull-down circuit is configured to, in a case where the transmission channel is a pull-down channel, convert the first current to obtain a pull-down current, and transmit the pull-down current to the switch transistor to drive the switch transistor to be turned off, wherein the pull-down current is the second current; and
the clamp circuit is configured to, in a case where the transmission channel is the pull-up channel and the gate voltage of the switch transistor is greater than or equal to a predetermined voltage, pull down the pull-up current to a predetermined current to clamp a gate-source voltage of the switch transistor.

3. The gate driver circuit according to claim 2, wherein the output pull-up circuit comprises a first current mirror, wherein
a first terminal of the first current mirror is configured to be connected to the supply voltage, a second terminal of the first current mirror is electrically connected to the third terminal of the channel selection circuit, and a third terminal of the first current mirror is electrically connected to the gate electrode of the switch transistor, and
the first current mirror is configured to convert the first current to obtain the pull-up current.

4. The gate driver circuit according to claim 3, wherein the first current mirror comprises a first N-type transistor and a second N-type transistor;
wherein a first terminal of the first N-type transistor is configured to be connected to the supply voltage, a control terminal of the first N-type transistor is electrically connected to a control terminal and a first terminal of the second N-type transistor, a second terminal of the first N-type transistor and a second terminal of the second N-type transistor are both electrically connected to the gate electrode of the switch transistor, and the first terminal of the second N-type transistor is further electrically connected to the third terminal of the channel selection circuit.

5. The gate driver circuit according to claim 2, the output pull-up circuit comprises a first current mirror, a first transistor, and a first voltage-limiting assembly, wherein
a first terminal of the first transistor is configured to be connected to the supply voltage, a second terminal of the first transistor is electrically connected to a first terminal of the first current mirror, a second terminal of the first current mirror is electrically connected to a first terminal of the first voltage-limiting assembly, a second terminal of the first voltage-limiting assembly is electrically connected to the third terminal of the channel selection circuit, a third terminal of the first current mirror is electrically connected to the gate electrode of the switch transistor, and a control terminal of the first transistor is electrically connected between the second terminal of the first voltage-limiting assembly and the third terminal of the channel selection circuit,
the first current mirror is configured to convert the first current to obtain the pull-up current, and
the first voltage-limiting assembly is configured to turn on the first transistor to output the pull-up current.

6. The gate driver circuit according to claim 5, wherein the first current mirror comprises a first N-type transistor and a second N-type transistor;
wherein a first terminal of the first N-type transistor is electrically connected to the second terminal of the first transistor, a control terminal of the first N-type transistor is electrically connected to a control terminal and a first terminal of the second N-type transistor, a second terminal of the first N-type transistor and a second terminal of the second N-type transistor are both electrically connected to the gate electrode of the switch transistor, and the first terminal of the second N-type transistor is further electrically connected to the first terminal of the first voltage-limiting assembly.

7. The gate driver circuit according to claim 2, wherein the output pull-down circuit comprises a second current mirror, wherein
a first terminal of the second current mirror is electrically connected to the fourth terminal of the channel selection circuit, a second terminal of the second current mirror is electrically connected to the source electrode of the switch transistor, and a third terminal of the second current mirror is electrically connected between the third terminal of the output pull-up circuit and the gate electrode of the switch transistor, and
the second current mirror is configured to convert the first current to obtain the pull-down current.

8. The gate driver circuit according to claim 7, wherein the second current mirror comprises a third N-type transistor and a fourth N-type transistor;
wherein a first terminal of the third N-type transistor is electrically connected between the third terminal of the output pull-up circuit and the gate electrode of the switch transistor, a control terminal of the third N-type transistor is electrically connected to a control terminal and a first terminal of the fourth N-type transistor, a second terminal of the third N-type transistor and a second terminal of the fourth N-type transistor are both electrically connected to the source electrode of the switch transistor, and the first terminal of the fourth N-type transistor is further electrically connected to the fourth terminal of the channel selection circuit.

9. The gate driver circuit according to claim 2, wherein the output pull-down circuit comprises a second current mirror, a second transistor, and a second voltage-limiting assembly, wherein
a first terminal of the second voltage-limiting assembly is electrically connected to the fourth terminal of the channel selection circuit, a second terminal of the second voltage-limiting assembly is electrically connected to a first terminal of the second current mirror, a second terminal of the second current mirror is electrically connected to a second terminal of the second transistor, a first terminal of the second transistor is electrically connected between the third terminal of the output pull-up circuit and the gate electrode of the switch transistor, a third terminal of the second current mirror is electrically connected to the source electrode of the switch transistor, and a control terminal of the second transistor is electrically connected between the first terminal of the second voltage-limiting assembly and the fourth terminal of the channel selection circuit,
the second current mirror is configured to convert the first current to obtain the pull-down current, and
the second voltage-limiting assembly is configured to turn on the second transistor to output the pull-down current.

10. The gate driver circuit according to claim 9, wherein the second current mirror comprises a third N-type transistor and a fourth N-type transistor;
wherein a first terminal of the third N-type transistor is electrically connected to the second terminal of the second transistor, a control terminal of the third N-type transistor is electrically connected to a control terminal and a first terminal of the fourth N-type transistor, a second terminal of the third N-type transistor and a second terminal of the fourth N-type transistor are both electrically connected to the source electrode of the switch transistor, and the first terminal of the fourth N-type transistor is further electrically connected to the second terminal of the second voltage-limiting assembly.

11. The gate driver circuit according to claim 2, wherein the channel selection circuit comprises a level conversion circuit, a control circuit, and a channel output circuit; wherein
an input terminal of the level conversion circuit is configured to be connected to the control signal, an output terminal of the level conversion circuit is electrically connected to an input terminal of the control circuit, a first output terminal of the control circuit is electrically connected to a first control terminal of the channel output circuit, a second output terminal of the control circuit is electrically connected to a second control terminal of the channel output circuit, an input terminal of the channel output circuit is electrically connected to the output terminal of the first current output circuit, a first output terminal of the channel output circuit is electrically connected to the first input terminal of the output stage circuit, and a second output terminal of the channel output circuit is electrically connected to the second input terminal of the output stage circuit;
the level conversion circuit is configured to convert the control signal to obtain a converted control signal, and transmit the converted control signal to the control circuit;
the control circuit is configured to obtain a first signal based on the converted control signal, and transmit the first signal to the channel output circuit, the first signal being used for determining whether the transmission channel for the first current is the pull-up channel or the pull-down channel; and
the channel output circuit is configured to transmit the first current to the output stage circuit based on the first signal.

12. The gate driver circuit according to claim 11, wherein the channel output circuit comprises a first P-type transistor and a second P-type transistor;
wherein a second terminal of the first P-type transistor and a second terminal of the second P-type transistor are both electrically connected to the output terminal of the first current output circuit, a control terminal of the first P-type transistor is electrically connected to the second output terminal of the control circuit, a first terminal of the first P-type transistor is electrically connected to the second input terminal of the output stage circuit, a control terminal of the second P-type transistor is electrically connected to the first output terminal of the control circuit, and a first terminal of the second P-type transistor is electrically connected to the first input terminal of the output stage circuit.

13. The gate driver circuit according to claim 11, wherein the first current output circuit comprises a current generation circuit and a third current mirror; wherein
an input terminal of the current generation circuit is configured to receive a digital signal, an output terminal of the current generation circuit is electrically connected to a first terminal of the third current mirror, and a second terminal of the third current mirror is electrically connected to the first terminal of the channel selection circuit;
the current generation circuit is configured to generate a current corresponding to the digital signal, and transmit the current corresponding to the digital signal to the third current mirror; and
the third current mirror is configured to convert the current corresponding to the digital signal to obtain the first current.

14. The gate driver circuit according to claim 13, wherein the third current mirror comprises a third P-type transistor and a fourth P-type transistor;
wherein a second terminal of the third P-type transistor and a second terminal of the fourth P-type transistor are both configured to be connected to a first voltage, a first terminal of the third P-type transistor is electrically connected to the output terminal of the current generation circuit, a control terminal of the third P-type transistor and a control terminal of the fourth P-type transistor, and a first terminal of the fourth P-type transistor is electrically connected to the first terminal of the channel selection circuit, wherein the first voltage is greater than a source voltage of the switch transistor and the gate voltage of the switch transistor.

15. The gate driver circuit according to claim 13, further comprising: a pulse current output circuit and a switch circuit; wherein
a first terminal of the pulse current output circuit is electrically connected to a first terminal of the first current output circuit, a first input terminal of the pulse current output circuit is electrically connected to the first output terminal of the control circuit, a second input terminal of the pulse current output circuit is electrically connected to the second output terminal of the control circuit, an output terminal of the pulse current output circuit is electrically connected between the output terminal of the first current output circuit and the first terminal of the channel selection circuit, a first terminal of the switch circuit is electrically connected between the first output terminal of the control circuit and the first control terminal of the channel output circuit, a second terminal of the switch circuit is electrically connected between the second output terminal of the control circuit and the second control terminal of the channel output circuit, a third terminal of the switch circuit is electrically connected between the first output terminal of the channel output circuit and the first input terminal of the output stage circuit, a fourth terminal of the switch circuit is electrically connected to the gate electrode of the switch transistor, a fifth terminal of the switch circuit is electrically connected between the second output terminal of the channel output circuit and the second input terminal of the output stage circuit, and a sixth terminal of the switch circuit is electrically connected to the source electrode of the switch transistor;
the pulse current output circuit is configured to transmit a pulse current to the first current output circuit to accelerate turn-on of a transistor in the output stage circuit, the pulse current being used for increasing the first current; and
the switch circuit is configured to discharge, based on the first signal, a gate parasitic capacitor of the transistor in the output stage circuit to accelerate turn-off of the transistor in the output stage circuit.

16. The gate driver circuit according to claim 15, wherein the pulse current output circuit comprises a logic assembly, a third P-type transistor, and a current source; wherein
a first input terminal of the logic assembly is electrically connected to the first output terminal of the control circuit, a second input terminal of the logic assembly is electrically connected to the second output terminal of the control circuit, an output terminal of the logic assembly is electrically connected to the control terminal of the third P-type transistor, a second terminal of the third P-type transistor is electrically connected to the first terminal of the first current output circuit via the current source, and a first terminal of the third P-type transistor is electrically connected between the output terminal of the first current output circuit and the first terminal of the channel selection circuit; and
the logic assembly is configured to obtain a pulse signal by performing logic processing on the first signal, the pulse signal being used for controlling turn-on of the third P-type transistor.

17. The gate driver circuit according to claim 16, wherein the logic assembly comprises a first XOR gate device, a second XOR gate device, a first delay device, a second delay device, and a NOR gate device;
wherein a first input terminal of the first XOR gate device is electrically connected to the first output terminal of the control circuit, a second input terminal of the first XOR gate device is electrically connected to an output terminal of the first delay device, an input terminal of the first delay device is electrically connected between the first input terminal of the first XOR gate device and the first output terminal of the control circuit, an output terminal of the first XOR gate device is electrically connected to a first input terminal of the NOR gate device, a first input terminal of the second XOR gate device is electrically connected to the second output terminal of the control circuit, a second input terminal of the second XOR gate device is electrically connected to an output terminal of the second delay device, an input terminal of the second delay device is electrically connected between the first input terminal of the second XOR gate device and the second output terminal of the control circuit, an output terminal of the second XOR gate device is electrically connected to a second input terminal of the NOR gate device, and an output terminal of the NOR gate device is electrically connected to the control terminal of the third P-type transistor.

18. The gate driver circuit according to claim 15, wherein the switch circuit comprises a first switch assembly, a second switch assembly, a first diode assembly, and a second diode assembly;
wherein a first terminal of the first diode assembly and a control terminal of the first switch assembly are both electrically connected between the first output terminal of the control circuit and the first control terminal of the channel output circuit, a second terminal of the first diode assembly and a second terminal of the first switch assembly are both electrically connected to the source electrode of the switch transistor, a first terminal of the first switch assembly is electrically connected between the second output terminal of the channel output circuit and the second input terminal of the output stage circuit, a first terminal of the second diode assembly and a control terminal of the second switch assembly are both electrically connected between the second output terminal of the control circuit and the second control terminal of the channel output circuit, a second terminal of the second diode assembly and a second terminal of the second switch assembly are both electrically connected to the gate electrode of the switch transistor, and a first terminal of the second switch assembly is electrically connected between the first output terminal of the channel output circuit and the first input terminal of the output stage circuit.

19. The gate driver circuit according to claim 18, wherein the third current mirror comprises a fourth P-type transistor, a fifth P-type transistor, and a sixth P-type transistor;
wherein a second terminal of the fourth P-type transistor, a second terminal of the fifth P-type transistor, and a second terminal of the sixth P-type transistor are all configured to be connected to a first voltage, a first terminal of the fourth P-type transistor is electrically connected to the output terminal of the current generation circuit, a control terminal of the fourth P-type transistor, a control terminal of the fifth P-type transistor, and a control terminal of the sixth P-type transistor, a first terminal of the fifth P-type transistor is electrically connected to a fifth terminal of the channel selection circuit, a first terminal of the sixth P-type transistor is electrically connected to the first terminal of the channel selection circuit, and a second terminal of the sixth P-type transistor is further electrically connected to the first terminal of the pulse current output circuit.

20. The gate driver circuit according to claim 19, wherein the channel selection circuit further comprises a seventh P-type transistor and an eighth P-type transistor;
wherein a second terminal of the seventh P-type transistor is electrically connected to the first terminal of the fifth P-type transistor, a control terminal of the seventh P-type transistor is electrically connected between the second output terminal of the control circuit and the second control terminal of the channel selection circuit, a first terminal of the seventh P-type transistor is electrically connected to the first terminal of the second diode assembly, a second terminal of the eighth P-type transistor is electrically connected between the second terminal of the seventh P-type transistor and the first terminal of the fifth P-type transistor, a control terminal of the eighth P-type transistor is electrically connected between the first output terminal of the control circuit and a first control terminal of the channel selection circuit, and a first terminal of the eighth P-type transistor is electrically connected to the first terminal of the first diode assembly.

21. A chip, comprising: a gate driver circuit, wherein the gate driver circuit comprises: a first current output circuit, a channel selection circuit, and an output stage circuit; wherein
an output terminal of the first current output circuit is electrically connected to a first terminal of the channel selection circuit, a second terminal of the channel selection circuit is configured to receive a control signal, the control signal being used for controlling the gate driver circuit to drive a switch transistor to be turned on or turned off, a third terminal of the channel selection circuit is electrically connected to a first input terminal of the output stage circuit, a fourth terminal of the channel selection circuit is electrically connected to a second input terminal of the output stage circuit, and an output terminal of the output stage circuit is electrically connected to a gate electrode of the switch transistor, wherein one control circuit is arranged in the channel selection circuit;
the first current output circuit is configured to transmit a first current to the channel selection circuit, the first current serving as a reference current;
the channel selection circuit is configured to select a transmission channel for the first current based on the control signal, and transmit the first current to the output stage circuit over the transmission channel; and
the output stage circuit is configured to output a second current based on the first current to drive the switch transistor to be turned on or turned off, the second current being used for pulling up or pulling down a gate voltage of the switch transistor.
